(19) United States
(12) Patent Application Publication
(10) Pub. No.: US 2008/0079460 A1
(43) Pub. Date: Apr. 3, 2008

(54) Programmable logic cell, configurable cell, configurable cell arrangement, configurable logic array, mask programmable basic cell, mask programmable gate array and method

(75) Inventors: Francisco-Javier Veredas-Ramirez, Munchen (DE); Siegmar Koeppe, Munchen (DE)

Correspondence Address: Maginot, Moore & Beck;Chase Tower, Suite 3250, 111 Moument Circle, Indianapolis, IN, 46204, US

(73) Assignee: Infineon Technologies AG, Munchen (DE)

(21) Appl. No.: 11/540,490

(22) Filed: Sep. 29, 2006

(51) Int. Cl. H03K 19/177

(52) U.S. Cl. 326/41

(57) ABSTRACT

A mask programmable logic cell for configuration of at least one either LUT-based and MUX-based configurable cell comprises a first set of 2:1 multiplexers each having two input terminals and one select terminal and a second set of 4:1 multiplexers each having four input terminals and comprising three hierarchal arranged 2:1 multiplexers. A LUT-based configurable cell, a MUX-based configurable cell arrangement and a configurable logic array is provided. Furthermore, a mask programmable basic cell and a mask programmable gate array is provided.

### TECHNICAL FIELD

The present invention relates to a mask programmable logic cell, a LUT-based configurable cell, a MUX-based configurable cell arrangement and a configurable logic array. The invention further relates to a mask programmable basic cell, a mask programmable gate array and a method for generating a mask for a mask programmable gate array.

### BACKGROUND

Programmable logic arrays are typically generic and comprise very regular architectures for providing the logic operations. A programmable logic array includes only a few types of configurable cells such as:
logic cells,
signal input cells (signal fan-in),
signal output cells (signal fan-out),
switching matrix,
input/output pins (I/O-pins).

The logic cells execute signal processing on the bit level. The signal input cells receive an input signal for example from an interconnect bus, which is fed into the logic cells. The signal output cells forward an output signal of a logic cell for example to the bus. The I/O-pins connect the programmable logic array with an external system for example with another circuit.

Programmable logic arrays also include a large number of switches, which are controlled by configuration bits, enabling a large number of signal paths within the interconnecting network of the programmable logic array to be set. A certain function of a programmable logic array is defined by its given configuration bits which are usually stored in configuration bit memory cells.

One representative of a programmable logic array is the so called field programmable gate array, hereinafter shortly referred to as FPGA. FPGAs represent a group of free programmable logic circuits which can be programmed by the user himself. With FPGAs digital circuits, any user defined functionality can be realized which otherwise have to be configured by single application specific integrated circuits (ASICs). These ASICs have predefined functions. The great benefit of FPGAs consists in the possibility to change the functionality of the FPGA by the user during the design or synthesis of the digital circuit to provide improvements of the circuit and/or to correct errors within the circuit. Since the functionality of the FPGA is determined only by its configuration, the same FPGA may be used for many different circuit applications. Consequently, a huge number of different integrated circuits may be produced with the same FPGA device which is cost effective in comparison to the conventional production of ASICs especially when producing prototypes and small series of integrated circuits.

The central elements of a FPGA are formed by configurable (i.e. programmable) logic cells. A FPGA contains a multiplicity of such logic cells in which signal processing is carried out at the bit level. With these configurable logic cells, logic operations such as AND, OR, NOT, XOR, etc. can be realized.

There are basically two different possibilities to implement a logic cell. On the one hand a look-up table or shortly LUT-based configurable logic cell and on the other hand a multiplexer or shortly MUX-based configurable logic cell.

The LUT-based configurable logic cell for use in a FPGA typically contains a memory element to store the configuration data. Further, the configurable logic cell comprises a lock-up table, hereinafter shortly referred to as LUT, which permits the implementation of a Boolean function with an input variable (bit) and one output variable (bit). In this case by means of a multiplexer tree whose branches are fed by bits stored in memory cells, in every work step a bit is read out dependent on the input variables which control the different multiplexers of the LUT. Thus, LUT-based FPGAs show a high programmable flexibility. Theoretically, any function can be met between the inputs and the output of the LUT.

The automated design of configurable logic cells is based on its so-called synthesis. In this case, special synthesis tools map a desired logic function in high level language description, like VHDL (Very high speed integrated circuit Hardware Description Language), onto a plurality of configurable logic cells. The design may be automated. Benefits of FPGAs lie in a fast time-to-market and nonrecurring engineering costs since these engineering costs already include the cost of the user which provides the integrated circuit and the costs for providing the masks of the integrated circuit.

For providing the programmable flexibility the LUT-based FPGA needs much more area on the chip due to their need for memory and switching elements compared to conventional ASICs. Conventional LUTs with more than three inputs have a high degree of redundancy and unused capacities due to a high number of equivalent functions. For example, a look-up table having four inputs can represent 2¹⁶=65536 logic function. However, many of these functions can be traced back to other functions again through permutations of the inputs. For the implementation of the LUT within the logic cell, this means that a relatively large amount of area is required for the LUT which is in most applications not utilized appropriately.

In addition, LUT-based FPGAs possess a higher signal delay because of the regular formed interconnection lines and thus also show higher power consumption.

The MUX-based configurable logic cell for use in a FPGA typically contains multiplexers for generating the required Boolean (logic)functions. Compared to LUT-based FPGAs this enables a more dense implementation, however, with a restricted number of Boolean functions.

The common element in both above mentioned implementations of logic cell structure, i.e. the MUX-based configurable logic cell and the LUT-based configurable cell, is a multiplexer.

Another representative of a configurable (i.e. programmable) logic array is the so-called mask programmable gate array, hereinafter shortly referred to as MPGA, which in contrast to a FPGA contains mask programmable logic cells. MPGAs see a growing importance because of increasing process variations, the increase of mask design costs and turnaround times in deep sub-micron technologies. Also, system developing engineers often use FPGAs for rapid prototyping on system level. The prototype design is then often converted to an MPGA. To give an example, it is quite usual that one customer uses a FPGA for a low volume of devices and/or for design prototyping. Sometimes the same customer has the need to use the same FPGA design for a medium volume of devices, for example for MPGA devices. A fast conversion flow may be interesting especially with regard to a short as possible time-to-market period.

Different types of MPGAs are distinguished from each other: A CMOS-based MPGA, a cell-based MPGA and a LUT-based MPGA.

A CMOS-based MPGA typically comprises a very long strip of a large number of n-MOS and p-MOS transistors. Although the synthesis step is easy to perform in CMOS-based MPGAs, the placement and routing is inefficient because of the system complexity of current designs. Cell-based MPGAs and LUT-based MPGAs comprise a two-dimensional array of so-called basic cells. The basic cell in a cell-based MPGA has a reduced set of standard cells (i.e. AND, OR, flip-flops, buffers, etc.). The basic cell in a LUT-based MPGA comprises a set of LUTs, flip-flop and logic elements (e.g. AND, OR, XOR, etc.).

A fast turnaround time methodology consists in prototyping the design with a FPGA framework and then converting the design to an MPGA. A cell-based MPGA offers high density, however, the disadvantage of this approach is the need for re-synthesis and complete placement and routing of the different elements. A LUT based MPGA solves this problem, however, shows a lower density of the different elements within the MPGA.

### BRIEF DESCRIPTION OF THE DRAWINGS

For a more complete understanding of the embodiments of the present invention, reference is now made to the following description taken in conjunction with the accompanying drawings. Exemplary embodiments are explained in more detail below using the schematic figures of the drawing, in which:

FIG. 1 shows a first embodiment of a mask programmable logic cell according to the present invention;

FIG. 1A, 1B show the circuitry of a single 2:1 multiplexer and a 4:1 multiplexer arrangement, respectively, for the mask programmable logic cell in FIG. 1;

FIG. 1C shows a second embodiment of a mask programmable logic cell according to the present invention;

FIG. 2 shows a third embodiment of a mask programmable logic cell according to the present invention;

FIG. 2A show the circuitry of a 4:1 single multiplexer for the mask programmable logic cell in FIG. 2;

FIG. 3 shows a LUT-based configurable cell for illustrating a first application of the mask programmable logic cell according to FIG. 1C;

FIG. 4 shows a look-up table (LUT) for the LUT-based configurable cell in FIG. 3;

FIG. 5 shows a combinational multiplexer-based configurable cell to illustrate a second application of the mask programmable logic cell according to FIG. 1;

FIG. 6 shows a sequential multiplexer-based configurable cell for illustrating a third application of the mask programmable logic cell according to FIG. 1C;

FIGS. 7A, 7B show two different multiplexer configurations for the generation of an AND- and OR-operation;

FIG. 8 shows a flow chart of the methodology of the conversion design flow for the generation of a mask for a mask programmable gate array using mask programmable logic cells according to FIGS. 1 or 2;

FIG. 9 shows the architecture of an MPGA;

FIG. 10 shows an exemplary embodiment of a mask programmable basic cell according to the present invention;

FIG. 11 shows a cut-out of the layout of a basic cell array based on basic cells as illustrated in FIG. 10;

FIGS. 12A-12C show the implementation of a five input NAND element using one single basic cell of FIG. 10;

FIGS. 13A-13C show the implementation of one two input NAND element and one three input NAND element using one single basic cell of FIG. 10;

FIGS. 14A-14C show the implementation of one five input NOR element using one and a half basic cells of FIG. 10;

FIGS. 15A-15F show the implementation of a MUX-based configurable cell using four basic cells of FIG. 10;

FIGS. 16A-16F show the implementation of a settable D flip-flops using three basic cells of FIG. 10.

In all figures of the drawings, elements and signals which are the same or have the same function have been provided with the same reference symbols—unless explicitly stated otherwise.

### DETAILED DESCRIPTION OF EMBODIMENTS

According to one embodiment, a single architecture of a mask programmable logic cell is usable as well as providing programmable, configurable FPGAs of a hard wired LUT-based FPGA and a MUX-based FPGA. According to one embodiment, only a set of single 2:1 multiplexers and 4:1 multiplexers are provided.

At least some embodiments of the present invention further provide a mask programmable logic cell equivalent of two different architectures: On one hand the MUX-based logic cells and on the other hand the LUT-based logic cells. These embodiments allow within the conversion flow for designing a configurable FPGA two different architectures. According to some embodiments, it is possible to use at least two different methodologies and/or architectures to program the mask programmable logic cell according to the present invention.

Some embodiments of the present invention are further directed to a basic cell that provides a fast design and manufacturing. This basic cell features high density comparable to cell based MPGA designs while retaining faster conversion from a FPGA over cell based MPGA.

Select embodiments of the present invention further provide only one generic basic cell within a MPGA-based array with a first and a second strip of transistors of opposite conductivity types to provide all required functionalities within an MPGA array. The basic cell may also be used to implement predefined and complex structures such as logic functions, flip-flops, multiplexers or even more complex circuits. A fast turnaround time may be achieved using an (emulated) MUX-based basic cell with a design or a map previously in another MUX-based FPGA.

Some embodiments of the invention provide a mask programmable logic cell for configuration of at least one either LUT-based or MUX-based configurable cell, comprising: a first set of 2:1 multiplexers each comprising at least two input terminals and at least one select terminal, a second set of 4:1 multiplexers each comprising at least four input terminals and at least two select terminals.

In a further embodiment each of the 4:1 multiplexers of the second set comprises three hierarchically arranged 2:1 multiplexers.

In a further embodiment an amount N of input terminals of the configurable cells is at least 4.

In a further embodiment the first set comprises six 2:1 multiplexers.

In a further embodiment the second set comprises three 4:1 multiplexers.

In a further embodiment the mask programmable logic cell further comprising at least one buffer.

In a further embodiment the mask programmable logic cell further comprising at least one inverter.

In a further embodiment the mask programmable logic cell further comprising one flip-flop.

Some embodiments of the invention provide a LUT-based configurable cell, comprising at least one LUT and configured by at least one mask programmable logic cell, each of the mask programmable logic cells comprising a first set of 2:1 multiplexers each comprising two input terminals and at least one select terminal and a second set of 4:1 multiplexers each comprising four input terminals and at least two select terminals.

In a further embodiment each of the 4:1 multiplexers of the second set comprises three hierarchically arranged 2:1 multiplexers.

In a further embodiment an amount N of input terminals of the configurable cells is at least 4.

In a further embodiment the first set comprises six 2:1 multiplexers and the second set comprises three 4:1 multiplexers.

In a further embodiment the LUT is configured by using one single mask programmable logic cell comprising six 2:1 multiplexers and three 4:1 multiplexers, wherein the 2:1 multiplexers and 4:1 multiplexers are arranged within a hierarchical multiplexer tree comprising four hierarchical levels.

In a further embodiment the LUT-based configurable cell further comprising a set of memory cells, wherein each of the memory cells is designed to store one input variable and to be connected with one input terminal of one of the 2:1 multiplexer within the lowest hierarchical level of the multiplexer tree.

In a further embodiment the LUT-based configurable cell further comprising a flip-flop arranged between an output of the LUT and a first output terminal of the LUT-based configurable cell.

In a further embodiment the output of the LUT is further connected to a second output terminal of the LUT-based configurable cell.

Some embodiments of the invention provide a MUX-based configurable cell arrangement, comprising at least one combinational MUX-based configurable cell implemented from resources of a mask programmable logic cell wherein the resources comprise a first set of 2:1 multiplexers each comprising two input terminals and at least one select terminal and a second set of 4:1 multiplexers each comprising four input terminals and at least two select terminals.

In a further embodiment each of the 4:1 multiplexers of the second set comprises three hierarchically arranged 2:1 multiplexers.

In a further embodiment the combinational MUX-based configurable cell comprises one 4:1 multiplexer, one logic OR-element and one logic AND-element.

Further embodiments of the invention provide a MUX-based configurable cell arrangement, comprising at least one sequential MUX-based configurable cell implemented from resources of a mask programmable logic cell wherein the resources comprise, a first set of 2:1 multiplexers each comprising two input terminals and at least one select terminal and a second set of 4:1 multiplexers each comprising four input terminals and at least two select terminals.

In a further embodiment each of the 4:1 multiplexers of the second set comprises three hierarchically arranged 2:1 multiplexers.

In a further embodiment the sequential MUX-based configurable cell comprises one 4:1 multiplexer, one logic OR-element, one logic AND-element and one flip-flop.

In a further embodiment the MUX-based configurable cell arrangement further comprises two combinational MUX-based configurable cell implemented from resources of the mask programmable logic cell and one sequential MUX-based configurable cell.

Some embodiments of the invention provide a configurable logic array comprising a plurality of configurable cells and further comprising: at least one LUT-based configurable cell, comprising at least one LUT implemented from resources of a mask programmable logic cell wherein the resources comprise a first set of 2:1 multiplexers each comprising two input terminals and at least one select terminal and a second set of 4:1 multiplexers each comprising four input terminals and at least two select terminals, and at least one MUX-based configurable cell arrangement, comprising at least one MUX-based configurable cell implemented from resources of the mask programmable logic cell.

In a further embodiment each of the 4:1 multiplexers of the second set comprises three hierarchically arranged 2:1 multiplexers.

Some embodiments of the invention provide a mask programmable basic cell for a mask programmable gate array (MPGA), the mask programmable basic cell comprising: a first and a second supply line, a first transistor strip to provide a first amount of first transistors of a first conductivity type, a second transistor strip to provide a second amount of second transistors of a second conductivity type opposite to the first conductivity type.

In a further embodiment the first and the second amount are equal.

In a further embodiment the first and second amount is five or ten.

In a further embodiment the first and second amount is four or six.

In a further embodiment the first amount is twice the second amount.

In a further embodiment the first transistors are arranged adjacent to the first supply line and the second transistors are arranged adjacent to the second supply line.

In a further embodiment the first and second transistors are field effect controlled transistors.

In a further embodiment the first transistors are PMOS transistors and the second transistors are NMOS transistors.

In a further embodiment adjacent transistors of the first transistors and second transistors comprise a doped region.

In a further embodiment all adjacent transistors of the first transistors and all adjacent transistors of the second transistors comprise respectively a doped region.

In a further embodiment all of the first transistors are arranged in a first row on the first transistor strip and all of second transistors are arranged in a second row on the second transistor strip.

In a further embodiment at least one of the first and second row is linear.

Some embodiments of the invention provide a mask programmable gate array, comprising: a plurality of input/output terminals, an array comprising a plurality of mask programmable basic cells, the layout of the mask programmable basic cell comprising a first and a second supply line, a first transistor strip to provide a first amount of first transistors of a first conductivity type, and a second transistor strip to provide a second amount of second transistors of a second conductivity type opposite to the first conductivity type.

In a further embodiment the first and the second amount is five or ten.

In a further embodiment the first amount is twice the second amount.

In a further embodiment the first transistors are arranged adjacent to the first supply line and the second transistors are arranged adjacent to the second supply line.

In a further embodiment the first transistors are PMOS transistors and the second transistors are NMOS transistors.

In a further embodiment the mask programmable gate array further comprising at least one first NAND-element having five input terminals and one output terminal, wherein each one of the NAND-elements is realized my means of one single mask programmable basic cell.

In a further embodiment the mask programmable gate array further comprising at least one logic element, each of the logic elements comprising one second NAND-element having two input terminals and one output terminal and one third NAND-element having three input terminals and one output terminal, wherein each one of the logic elements is realized my means of one single mask programmable basic cell.

In a further embodiment the mask programmable gate array further comprising at least one first NOR-element having five input terminals and one output terminal, wherein each one of the NOR-elements is realized by means of two single mask programmable basic cells which are arranged adjacent to each other to provide pMOS transistors with double width.

In a further embodiment the mask programmable gate array further comprising at least one MUX-based configurable cell comprising a 4:1 multiplexer, a OR-NOR-element and a AND-NAND-element each having two input terminals, wherein the OR-NOR-element has a first and second output to provide complementary signals and wherein the AND-NAND-element has a third and fourth output to provide complementary signals.

In a further embodiment each one of the MUX-based configurable cells is realized by means of four single mask programmable basic cells which are arranged adjacent to each other.

In a further embodiment each of the MUX-based configurable cells comprises one hierarchical arranged 4:1 multiplexer comprising three 2:1 multiplexers.

In a further embodiment the mask programmable gate array further comprising at least one inverter.

In a further embodiment the mask programmable gate array further comprising at least one D-flip flop, wherein each one of the D-flip flops is realized my means of at least two single mask programmable basic cells which are arranged adjacent to each other.

In a further embodiment the D-flip-flop is a settable D-flip-flop comprises two fourth NAND-elements, two 2:1 multiplexers and at least one inverter arranged in series connection to each other with the inverter arranged at the output side of the D-flip-flop and one 2:1 multiplexer and one NAND-element each form a stage of the D-flip-flop.

In a further embodiment the mask programmable gate array further comprising at least one common first supply line and at least one common second supply line commonly, each one of the common first and second supply lines is designed to be used by at least two mask programmable basic cells.

In a further embodiment the mask programmable gate array further comprising at least one data line to provide a static signal related to a first logical level.

Some embodiments of the invention provide a method for generating a mask for a mask programmable gate array using mask programmable logic cells for configuration of at least one either LUT-based or MUX-based configurable cell comprising: providing an user defined design of an integrated circuit; performing a logic synthesis depending on the defined design of the integrated circuit.

In a further embodiment the mask programmable logic cell comprising: a first set of 2:1 multiplexers each comprising at least two input terminals and at least one select terminal, a second set of 4:1 multiplexers each comprising at least four input terminals and at least two select terminals.

In a further embodiment the method further comprising after the step of performing a logic synthesis: performing a mask programmable routing for the integrated circuit; performing a mask generation for the integrated circuit; chip fabrication of the integrated circuit.

In a further embodiment the logic synthesis comprises the step of a multiplexer based synthesis followed by a corresponding first placement step.

In a further embodiment the logic synthesis comprises the step of a LUT-based synthesis followed by a corresponding second placement step.

In a further embodiment the method allows for the same integrated circuit a LUT-based synthesis and multiplexer based synthesis during the step of performing a logic synthesis.

In a further embodiment the design is a FPGA-circuit.

In a further embodiment the design is a MPGA-circuit.

In a further embodiment the method further comprising the generation of a manufacturer specific library which is adapted on the corresponding logic synthesis and which is constructed on the basis of a mask programmable basic cell.

In a further embodiment the mask programmable basic cell comprising: a first and a second supply line, a first transistor strip to provide a first amount of first transistors of a first conductivity type, a second transistor strip to provide a second amount of second transistors of a second conductivity type opposite to the first conductivity type.

In a further embodiment after the step of logic synthesis the method proceeds without a step of performing a mask programmable routing directly with the steps of: performing a mask generation for the integrated circuit; chip fabrication of the integrated circuit.

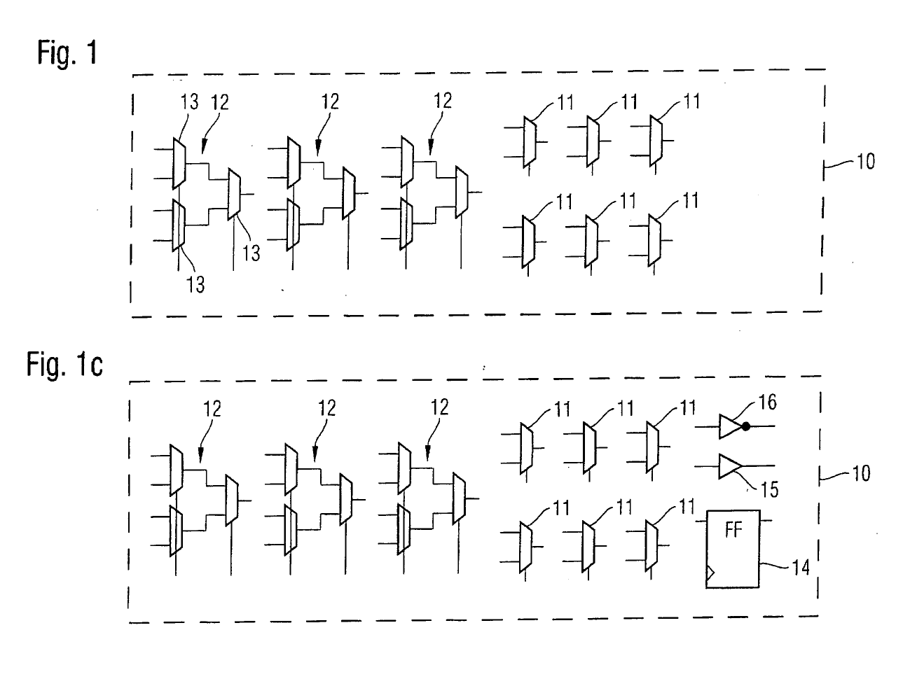

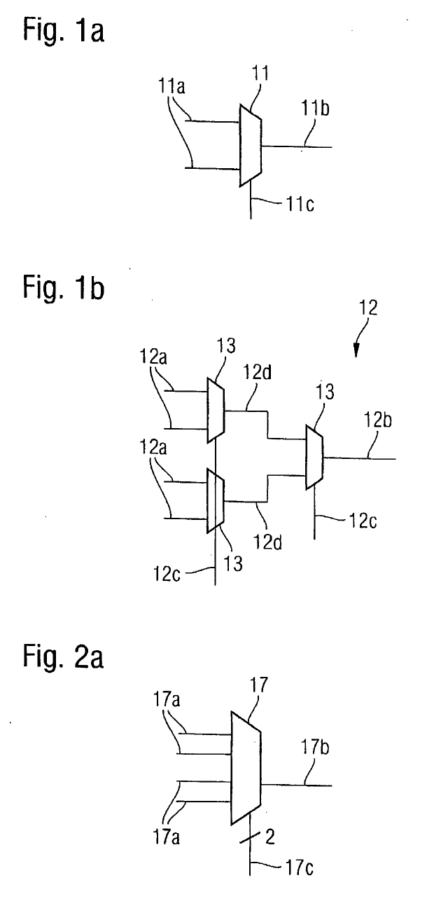

FIG. 1 illustrates an embodiment of a mask programmable logic cell denoted by reference symbol 10. FIG. 1 shows one exemplary embodiment of a minimal schematic of the mask programmable logic cell. The mask programmable logic cell 10 comprises six single multiplexers 11 and three multiplexer arrangements 12 which each in turn comprise three single multiplexers 13.

FIG. 1A shows the circuitry of a single multiplexer 11. This multiplexer 11 is hereinafter referred to as a 2:1 multiplexer 11 since it comprises two input terminals 11a and one single output terminal 11b. In addition the 2:1 multiplexer 11 also comprises a control terminal 11c for controlling the function of the multiplexer 11 by selecting the desired input terminal 11a.

FIG. 1B shows the circuitry of the multiplexer arrangement 12. This multiplexer arrangement 12 is hereinafter referred to as a 4:1 multiplexer 12, since it comprises four input terminals 12a and one single output terminal 12b. Further, the multiplexer arrangement 12 comprises two control terminals 12c for controlling purposes. The multiplexer arrangement 12 is composed of a total number of three 2:1 multiplexers 13 such as illustrated in FIG. 1A. Two of these 2:1 multiplexers 13 are connected to the four input terminals 12a so that these 2:1 multiplexers 13 are arranged in parallel to each other with respect to their input sides and output sides. Each of the two 2:1 multiplexers 13 comprises an output terminal coupled to the input terminal of the third 2:1 multiplexer 13.

FIG. 1C shows a more detailed embodiment of a mask programmable logic cell according to an embodiment of the present invention. In addition to the three 4:1 multiplexers 12 and six 2:1 shown in the embodiment in FIG. 1 the mask programmable logic cell 10 in FIG. 1C additionally comprises a single flip-flop 14 and a buffer 15 and a inverter 16.

In the embodiment according to FIG. 1C, the flip-flop 14 comprises one signal input and one signal output and a clock input.

While the present embodiment according to FIG. 1C shows only one buffer 15 and one inverter 16, it is to be understood that other embodiments may comprise a set of inverters or a set of buffers or a set of inverters and a set of buffers.

A buffer 15 may be used to drive output signals having a high output load or output signals on long wired connections. A dedicated clock tree may be provided having high strength buffers 15 within the logic cell 10.

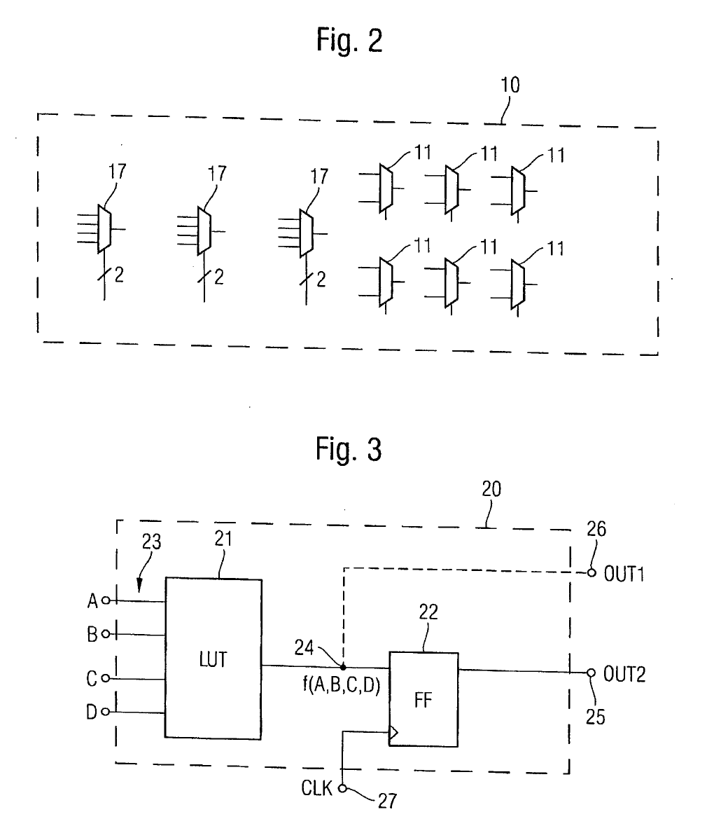

The function of an inverter 16 is to complement its input signal. For example, an input signal having a low voltage level is transferred to a signal having a high logic level and vice versa. The incorporation the inverter 16 within a logic cell 10 as shown in FIG. 2 may avoid inefficiencies of the synthesis, however other embodiments encompass a mask programmable logic cell without the inverter 16.

The configuration of a mask programmable logic cell 10 as described above fits well with commercial FPGA technologies such as a MUX-based FPGA and a LUT-based FPGA. All the elements of the mask programmable logic cell 10, i.e., the 2:1 and 4:1 multiplexers 11, 12, the flip-flop 14, the buffers 15 and inverters 16 are predefined within the MPGA. The MPGA is programmed by connecting the input terminals and output terminals of these elements 11, 12, 14, 15, 16 with user-defined metal masks and vias.

By providing a mask programmable logic cell 10 such as that shown in FIG. 1 and 1C and by appropriate interconnection and programming it is possible to realize a lot of MUX-based and LUT-based FPGAs. Examples thereof are shown in more detail on the basis of the embodiments in FIGS. 3-6.

FIG. 2 shows another embodiment of a mask programmable logic cell. The mask programmable logic cell 10 comprises six single 2:1 multiplexers 11 (such as shown in FIG. 1A) and three single 4:1 multiplexers 17. FIG. 2A shows the circuitry of the single 4:1 multiplexer. A single 4:1 multiplexer 17 comprises four input terminals 17a, one single output terminal 17b and two control terminals 17c for controlling the function of the 4:1 multiplexer 17 by selecting the desired input terminal 17a.

FIG. 3 represents a block diagram of a LUT-based configurable cell for illustrating a first exemplary application of the mask programmable logic cell according to FIG. 2.

In FIG. 3 the LUT-based configurable logic cell 20 or shortly the logic cell is denoted by reference symbol 20. The logic cell 20 is created by means of the mask programmable logic cell 10 shown in FIG. 2. The logic cell 20 contains a LUT 21, which forms a read-out device, and a flip-flop 22. The LUT 21 comprises four input terminals 23 for receiving four input variables A, B, C, D (or input bits) and one single output terminal 24 for providing an output variable. A bit f(A, B, C, D) can be tapped off at the output terminal 24 of the LUT 21 in a manner dependent on the four input variables A-D. This bit f(A, B, C, D) is available as a first output signal OUT1 of the logic cell 20 at a first output terminal 26 (see doted line) while also feeding an input of the flip-flop 22 being arranged downstream to the LUT 21. The output of the flip-flop 22 forms a second output 25 of the logic cell 20, at which an output bit OUT2 selected as a result of the four input variables is read out. Thus, both output bits OUT1, OUT2 are a function of the input variables A, B, C, D.

The flip-flop 22 may also be bridged e.g., by a hard wire (not shown in FIG. 3) if a few combinatorial functions have to be realized by the logic cell 20. In this case, the flip-flop 22 can also be omitted so that the logic cell 20 only consists of the LUT 21.

The logic cell 20 further comprises a input clock terminal 27 for receiving a clock signal CLK. The clock signal may be an internal or external clock signal CLK.

Using a LUT 21 theoretically every visible mapping can be implemented between their input and output terminals 23, 24.

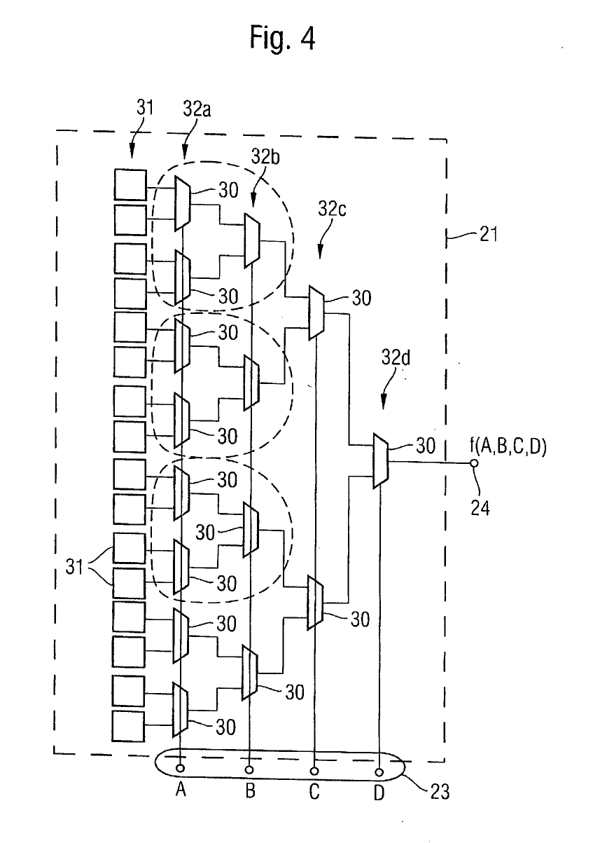

FIG. 4 represents a circuit diagram of a LUT 21 as shown in FIG. 3.

The LUT 21, which comprises four input terminals 23 and a single output terminal 24, further comprises a plurality of 2:1 multiplexers 30. In total, the LUT 21 comprises fifteen single 2:1 multiplexers 30 and 16 memory cells 31 holding the configuration data. The 2:1 multiplexers 30 each having two inputs are arranged in the form of a multiplexer tree resulting in a hierarchical arrangement of the multiplexers 30 with a total of four hierarchical levels 32a-32d. Each of these hierarchical levels 32a-32d is assigned to one of the input terminals 23 which are used to control the functionality of the different multiplexers 30.

The multiplexers 30 are arranged within the multiplexer tree in a manner that the number of multiplexers 30 is halved when going from a low hierarchical level of the LUT 21 to the next higher hierarchical level. Thus, in the lowest hierarchical level 32a there are eight multiplexers 30, whereas in the next higher hierarchical level 32b there are four multiplexers 30, in the third hierarchical level 32c there are two multiplexers 30 and in the highest hierarchical level 32d there is only one multiplexer 30.

In addition to the multiplexers 30, the LUT 21 further comprises a plurality of configuration memory cells 31. Each of these memory cells 31 is designed for storing a single bit. The two inputs of the 2:1 multiplexers 30 in the lowest hierarchical level 32a are in each case connected to the 1 bit output of two memory cells 31, whereas two respective memory cells 31 are assigned to each one of these multiplexers 30.

The control inputs 23 of the different multiplexers 30 are used, as usually in a LUT 21, as for receiving data signals. The four input signals A, B, C, D simultaneously control the multiplexers 30 of the LUT 21.

During the operation of the configurable logic cell 20 the input variables A,B,C,D are fed into input terminals 23. As a result of the setting of the multiplexers 30 that is thereby chosen the output of a memory cell 31 is connected to the output 24 of the LUT 21. Consequently, the bit stored in this memory cell 31 can be tapped off at the output 24. In other words, the bit that can be read out at the output 24 is a function of the input variables at the input terminals 23 and furthermore depends on the bits stored in the memory cells 31. The 16 memory cells 31 are therefore configured with bits in accordance with the synthesis carried out before the input variables are fed into the input terminals 23.

By using a logic cell 10 as shown in FIGS. 1 or 2 it a LUT 21 is provided. An example of such an implementation of a LUT 21 using three 4:1 multiplexers 12 and six 2:1 multiplexers 11 is also shown in FIG. 4. Here, each of the three 4:1 multiplexers 12 are marked with a dotted circle.

By providing a mask programmable logic cell 10 according to FIG. 2 which in addition to the three 4:1 multiplexers 12 and six 2:1 multiplexers 11 contains a flip-flop 14 it is possible not only to create a LUT 21 (as shown in FIG. 4) but also a whole LUT-based configurable cell 20 as shown in FIG. 3.

In the embodiments shown in FIGS. 1 to 4 a mask programmable logic cell 10 and a respective LUT-based configurable cell 20 and LUT 21 are shown which have an amount of N=4 inputs and one or two output terminals. However, the invention is not restricted to this exemplary embodiment of N=4 inputs. Especially, similar embodiments of the invention relate to any amount of N input terminals. If N is smaller than 4 the logic cell 10 according to the present invention is less complex and if N>4 the logic cell 10 is more complex. However, in practice, the number N of inputs is usually limited to 4 or 5 since less than four and/or more than five of inputs of the logic cells 10 are only rarely required within FPGA applications.

It is to be understood that by providing a mask programmable logic cell 10 it may also be possible to create a LUT 21 having less than 15 multiplexers 30 whereas in this case some of the 2:1 multiplexers 11 and/or some of the 4:1 multiplexers 12 within the logic cell 10 are not used and thus are redundant.

Besides creating LUT-based FPGAs (see FIGS. 3, 4) it is also possible to create MUX-based FPGAs with the same mask programmable logic cell 10 according to one embodiment of the present invention which will be addressed in detail below.

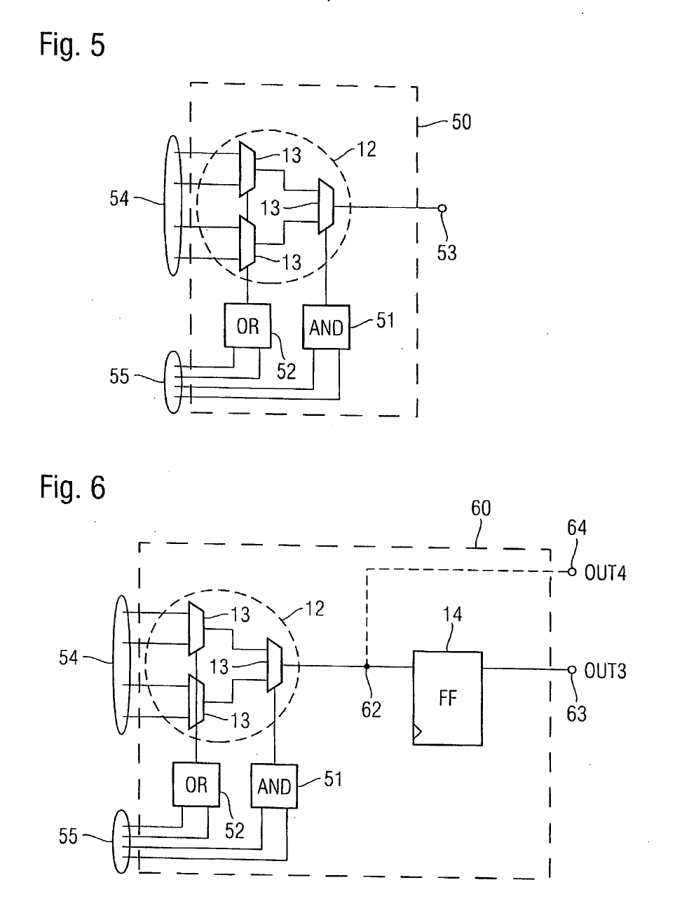

FIG. 5 represents a circuit diagram of a combinational MUX-based configurable cell for providing another application for the mask programmable logic cell according to one embodiment of the present invention.

The MUX-based configurable cell 50 in FIG. 5 comprises one 4:1 multiplexer 12, a logic AND-element 51 and a logic OR-element 52. The MUX-based configurable cell 50 comprises four input terminals 54 which are connected the four inputs of the 4:1 multiplexer 12. The MUX-based configurable cell 50 further comprises four input terminals 55, whereas two of these input terminals 55 are connected with inputs of the logic AND-element 51 and two of these input terminals 55 are connected with inputs of the logic OR-element 52. The input terminals are provided for receiving input signals. Each of the And- and OR-element 51, 52 comprises a single output terminal. The output terminals of the AND- and OR-elements 51, 52 are designed to control respective control terminals of the 2:1 multiplexers 13 within the 4:1 multiplexer 12 in such a way that the OR-element 52 controls the multiplexers 13 of the lowest hierarchical level and the AND-element 51 controls the single multiplexer 13 in the highest hierarchical level. The output of this highest level multiplexer 13 forms the output terminal 53 of this configurable cell 50.

It may also be possible, that the AND- and OR-elements 51, 52 are interchanged with respect to their input and output terminals, i.e. in this case the AND-element 51 controls the multiplexers 13 of the lowest hierarchical level and the OR-element 52 controls the single multiplexer 13 in the highest hierarchical level.

FIG. 6 shows a sequential multiplexer based configurable cell 60. The sequential multiplexer based configurable cell 60 in FIG. 6 comprises the same hierarchical structure as the combinational multiplexer based configurable cell 50 in FIG. 5 with an additional flip-flop 14 arranged between an output terminal 62 of the 4:1 multiplexer 13 and a first output terminal 63 of the whole configurable cell 60. In an optional configuration (see doted line in FIG. 6) the configurable cell 60 comprises (additionally or alternatively) a second output terminal 64. At the first and second output terminals 63, 64 first and second output signals OUT3, OUT4, respectively, may be tapped of.

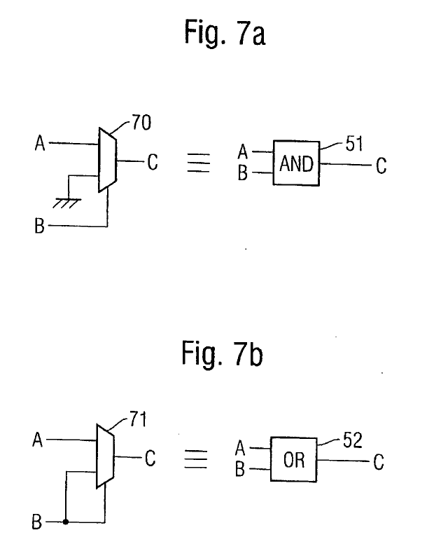

As shown in the exemplary illustration in FIGS. 7A, 7B, each of the AND-element 51 and the OR-element 52 may be realized by programming one single 2:1 multiplexers 70, 71.

For the AND-element 51, the first input forms one input of the multiplexer 70 and the second input forms the control terminal of this multiplexer 70. The second input of the multiplexer 70 is referenced to a low potential.

For the OR-element 52, a first input terminal of the multiplexer 71 forms a first input of the OR-element 52 and a second input terminal and the control terminal of the multiplexer 71 are connected to form a second input of the OR-element 52.

To realize the different interconnections of the AND-element 51 and OR-element 52, a metal layer and a via is used to configure the two different and independent multiplexers 70, 71 to form an AND-element and an OR-element and to connect the respective multiplexers 70, 71, which represent the AND- and OR-elements to form the combinational multiplexer based configurable cell 50 in FIG. 5 and the sequential multiplexer based configurable cell 60 in FIG. 6, respectively.

Since every AND-element 51 and OR-element 52 is realized by a single independent 2:1 multiplexer to implement the multiplexer based configurable cell in FIG. 5 two 2:1 multiplexers and one 4:1 multiplexer are required. Thus, for example the mask programmable cell of FIG. 1C provides resources for the implementation of two combinational multiplexer based cells 50 and one sequential multiplexer based cells 60. Therefore, besides the buffers 15 and inverters 16 all elements of the mask programmable logic cell 10 of FIG. 2 are used for this signal routing.

Thus, a mask programmable logic cell 10 according to the embodiment as shown in FIG. 2, the multiplexer based cell architectures shown in FIGS. 5, 6 may be generated and in detail it is possible to generate two combinational multiplexer based configurable cells 50 as shown in FIG. 5 and one sequential multiplexer based configurable cell 60 as shown in FIG. 6 by providing only one single mask programmable logic cell 10 according to the embodiment in FIG. 2.

Besides the combinational multiplexer based configurable cells 50 and sequential multiplexer based configurable cells 60 it is also possible to create other permutations and multiplexer based circuit arrangements by providing a single mask programmable logic cell 10 according to at least some embodiments of the present invention.

Again, the embodiments shown in FIG. 5, 6 are described with regard to N=8 inputs and a single output for each of the circuits shown therein. However, it may also be possible to vary N, accordingly, and/or use an optional second output terminal.

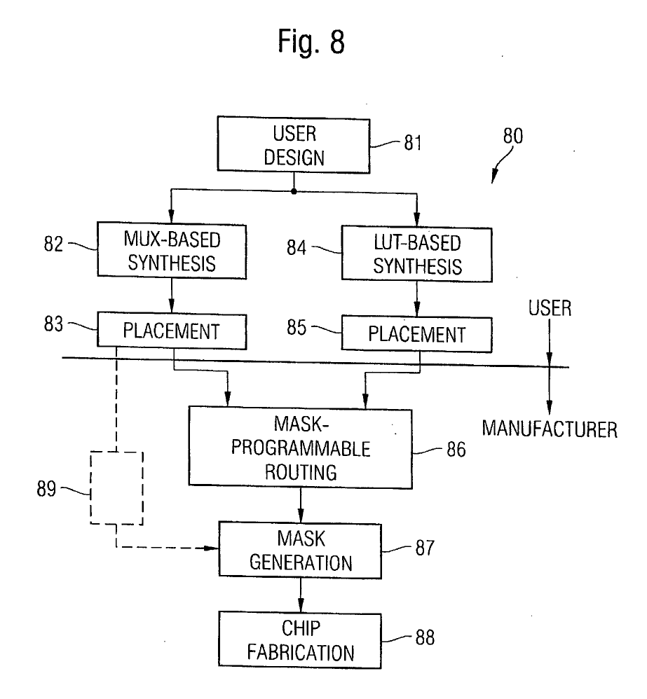

FIG. 8 shows a flow chart of the methodology of the conversion design flow for the generation of a mask for a mask programmable gate array using mask programmable logic cells according to some embodiments of the present invention.

In FIG. 8 the whole flow chart is denoted by reference symbol 80. In the first step 81 a user, for example a customer, defines a special FPGA or MPGA design. As can be seen in FIG. 8, there are two different possibilities for the logic synthesis. On the one hand there is the multiplexer based synthesis 82 followed by a placement step 83 and on the other hand there is a LUT-based synthesis 84 followed by a placement step 85. The placement step 85 may be different to the placement 83. The first synthesis leads to a multiplexer based FPGA and the second synthesis leads to a LUT-based synthesis. Both of them are executed by the respective customer or user. After the respective placement steps 83, 85 the further steps mask programmable routing 86, mask generation 87 and chip fabrication 88 are performed which is typically done by the respective semiconductor manufacturer.

Typically LUT-based synthesis 84 is more efficient in terms of area and delay. However, the multiplexer based synthesis 82 is more efficient with regard to the synthesis of control circuits. Therefore, often a trade-off has to be found which one of the two routes, on the one hand the multiplexer based synthesis 82 or on the other hand the LUT-based synthesis 84, is chosen. This trade-off is typically dependent on the used technology of the semiconductor manufacturer. With some embodiments of the present invention, an architecture is provided allowing both types of synthesis during the synthesis stage 82, 84.

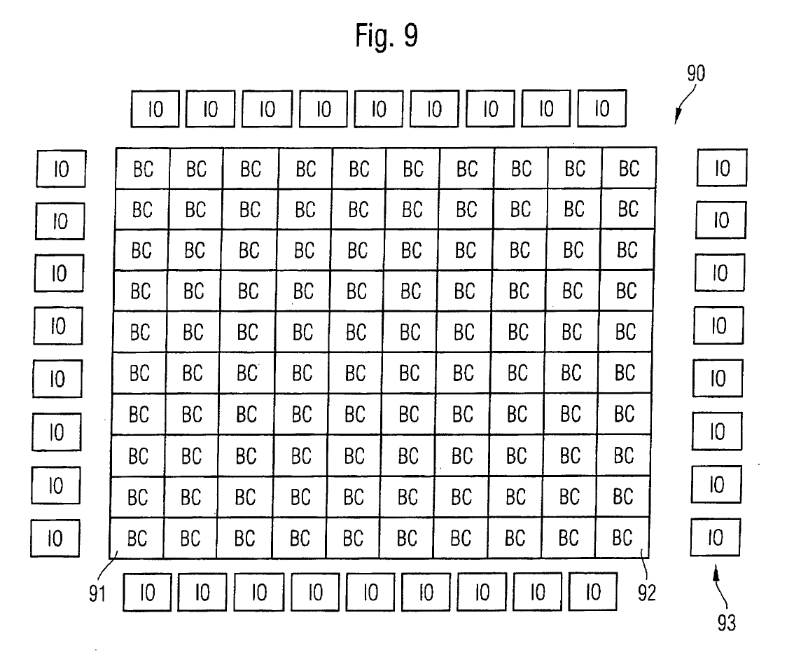

FIG. 9 shows the architecture of an MPGA.

In FIG. 9 the MPGA is denoted with reference symbol 90. The MPGA 90 consists of a two-dimensional array 91 of basic cells 92 (BC) and a set of input/output blocks 93 (IO) which are arranged adjacent to the outer portion of the MPGA array 91.

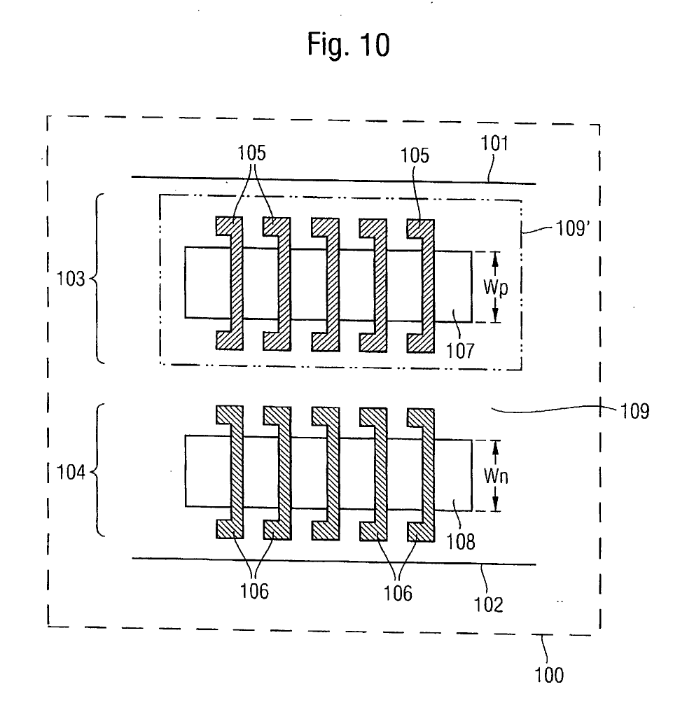

FIG. 10 shows an embodiment of a mask programmable basic cell according to an embodiment of the present invention.

The mask programmable basic cell—or shortly basic cell—is denoted with reference symbol 100. The mask programmable basic cell 100 is usable in a MPGA 90 such as shown in FIG. 9. The basic cell 100 is provided in typical CMOS technology.

A basic cell 100 comprises a first supply line 101 for a first supply voltage VDD, for example a positive supply voltage VDD, and a second supply line 102 for a second supply voltage VSS, for example a negative voltage or a reference voltage VSS such as the ground potential.

The basic cell 100 further comprises an upper transistor region 103 arranged adjacent to the first supply line 101 and a lower transistor region 104 arranged adjacent to the second supply line 102 and further arranged adjacent to the upper transistor region 103.

In the embodiment in FIG. 10, the transistor regions 103, 104 each comprise five single transistor gates 105, 106. Especially, each of the transistor regions 103, 104 forms a strip with each comprising five single transistor gates 105, 106. It is assumed that the transistor gates 105 in the transistor region 103 are designed to later form PMOS-type transistors and the transistor gates 106 in the transistor region 104 are designed to later form NMOS-type transistors.

Each of the transistor regions 103, 104 comprise a doped region 107, 108. The doped region 107, 108 later comprise the drain region, the source region and the channel region of a NMOS or a PMOS transistor, respectively, whereas within the basic cell 100 shown in FIG. 10 these drain regions and source regions are not yet connected and therefore are not yet defined. Although the doped regions 107, 108 are shown as rectangular regions in FIG. 10, it is noted that these doped regions 107, 108 typically (but not necessarily) do not have the same doping concentration. In fact, typically the channel region which is the region under the transistor gate comprises a lower doping concentration than the corresponding drain and source regions. Also each one of the doped regions 107, 108 does not need to have a homogenous doping concentration.

The hatched portions of the transistor gates 105, 106 represent the gate electrodes of the not yet connected PMOS and NMOS transistors 105, 106.

The channel width of the PMOS transistors 105 is denoted to as Wp and the channel width of the NMOS transistor 106 is denoted to as Wn.

It is further noted that FIG. 10 is only a schematic view and sizes shown FIG. 10 may not be implemented identical. For example, in the embodiment according to FIG. 10 the channel width Wp is illustrated nearly identical to the channel width Wn, whereas in a typical CMOS design the channel width Wp of the PMOS transistors 105 may be larger than the channel width Wn of the corresponding NMOS transistors.

The drain regions, source regions and channel regions within the doped regions 107, 108 are generated by semiconductor doping processes such as implantation and diffusion. The conductivity type of the channel region as well as the conductivity types of the source and drain regions are then determined by the type of the desired MOS-transistor and especially by its channel-type.

It is assumed that the semiconductor substrate 109 is in embodiment in FIG. 10 a p-type semiconductor substrate 109. Therefore, for realization of the PMOS transistors 105 it is necessary to incorporate an additional n-type region, e.g. an n-type well 109′ within the p-type semiconductor substrate 109 forming the transistor region 103.

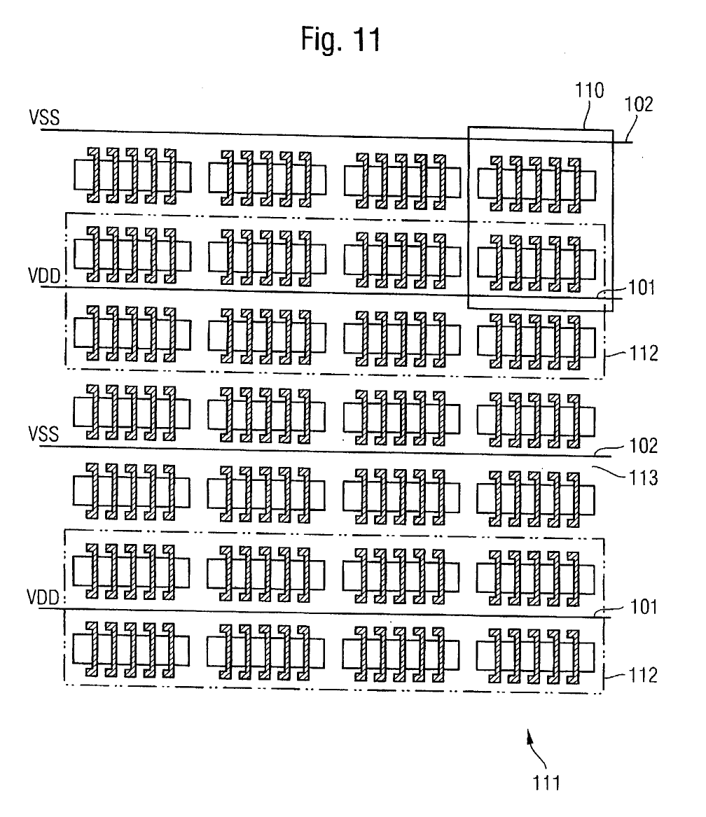

The basic cell 100 shown in FIG. 10 allows a fast design and manufacturing process. Further the structure of the basic cell 100 comprises a high regularity enabling high yield designs. By providing a basic cell 100 such as shown in FIG. 10 it is possible to generate different and very complex cell structures and logic elements with only one type of basic cells 100 (or at least some few different but nevertheless very-similar basic cells 100). This will be described in more detail hereinafter by exemplary embodiments with regard to FIGS. 11-16.

The generation of the different logic elements and programmable cells may be achieved easily by connecting the different transistor electrodes of the basic cell 100 e.g. with the supply lines 101, 102 or for the purpose of ESD prevention with signal lines that provide equivalent static data signals, with each other and/or with given output terminals. As a consequence of this, the basic cell design according to FIG. 10 supports any mapping at the design level and thus allows a free choice of mapping for creating different logic elements.

It is further noted that the embodiment of a basic cell shown in FIG. 10 illustrates only one exemplary embodiment of the design of a mask programmable basic cell 100. It is to be understood that by varying the amount of transistor gates 105, 106 within the transistor regions 103, 104 it is possible to provide different designs of a mask programmable basic cell 100 according to at least some embodiments of the present invention. For example, it may also be possible to provide a basic cell 100 having four PMOS transistors 105 and four NMOS transistors 106. Another possible design of a basic cell comprises six PMOS transistors 105 and six NMOS transistors 106. A further design of a mask programmable basic cell 100 comprises ten PMOS transistors 105 and ten NMOS transistors 106.

It is also noted that by varying the conductivity type of the semiconductor substrate 109, the well 109′ and/or the doped regions 107, 108 from p to n and vice versa and by varying the doping concentrations of these regions it is possible to provide an additional number of different designs of a mask programmable basic cell 100.

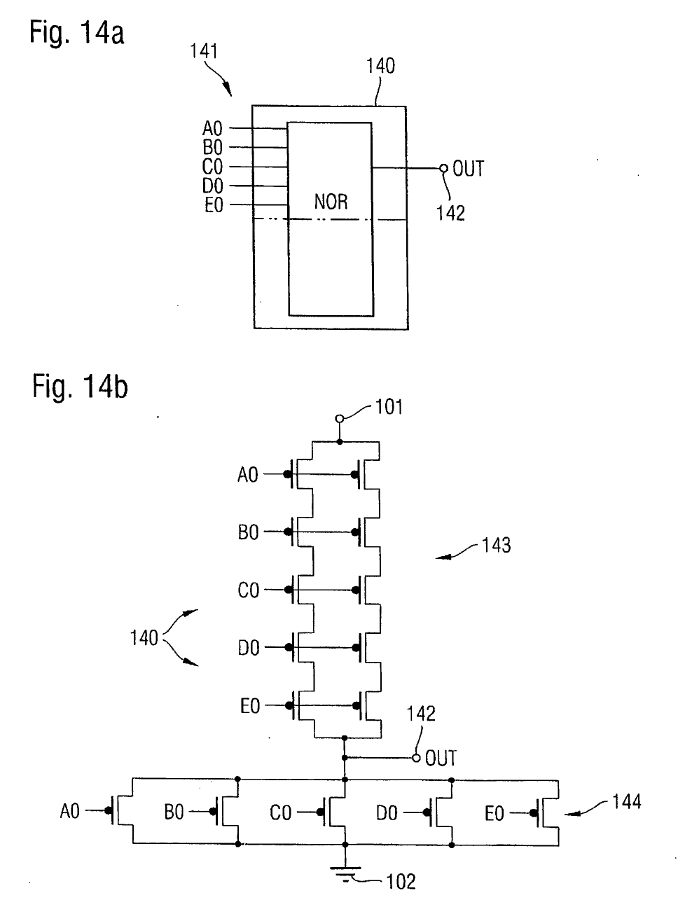

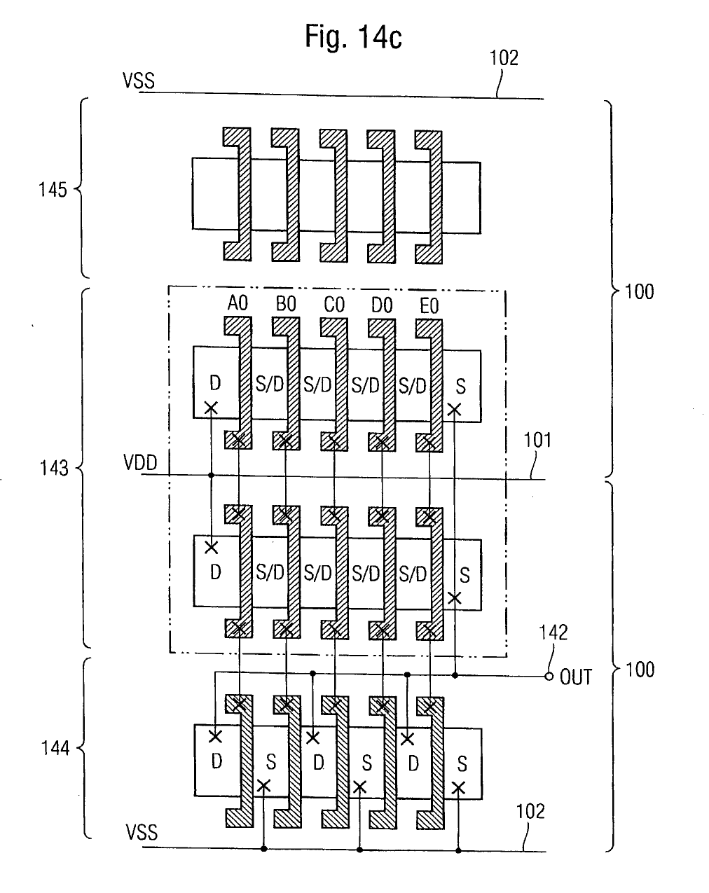

While embodiments provide an identical number of transistor portions 105, 106 within the different transistor regions 103, 104 of a given basic cell 100, it may also be possible (e.g. in the example in FIG. 14) to provide a different number of transistor portions 105, 106 within the different transistor regions 103, 104, for example to provide ten PMOS transistors 105 and five NMOS transistors 106 within the same given basic cell 100.

The complete array of the MPGA may then be constructed only by this type of basic cells 100 (comprising e.g. ten PMOS transistors 105 and five NMOS transistors 106). Alternatively, the array of the MPGA may also comprise only a few of these basic cells 100 and the other basic cells 100 may be e.g. such as shown in FIG. 10, i.e. comprising an equal number of PMOS transistors 105 and five NMOS transistors 106.

FIG. 11 shows a cut-out of a layout of a plurality of basic cells 100. These basic cells 100 may be used in the MPGA architecture shown in FIG. 9. Just to give an example, one of these basic cells is marked with reference number 110 at the above right edge of the array 111 in FIG. 11. The different basic cells of the cell array 111 are distributed in rows, whereas adjacent basic cells 100 may share a common supply line 101, 102. The dotted line marks a p-well 112 within the semiconductor substrate 113 and includes respective transistor regions 103 of different basic cells 100.

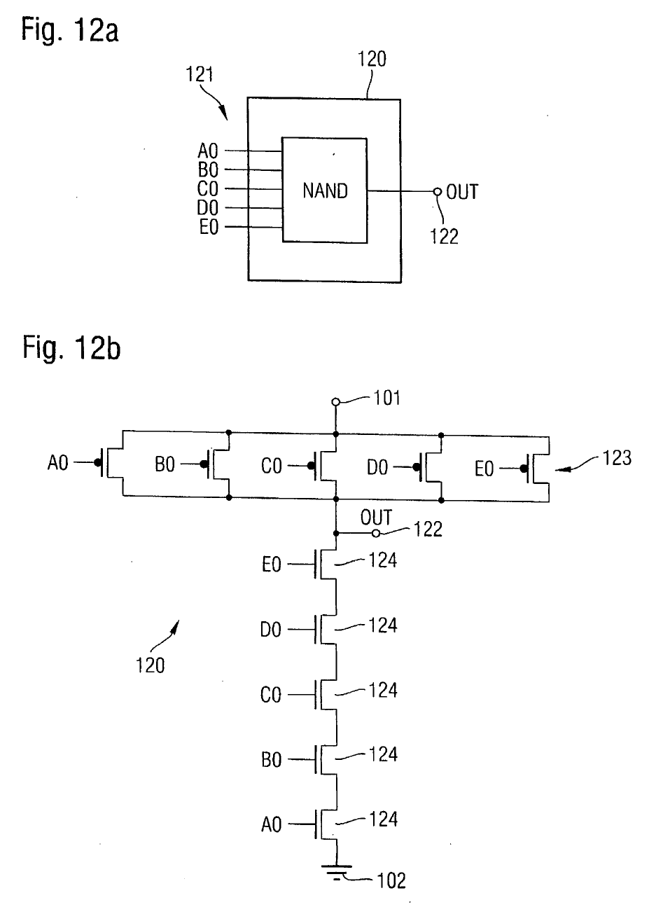

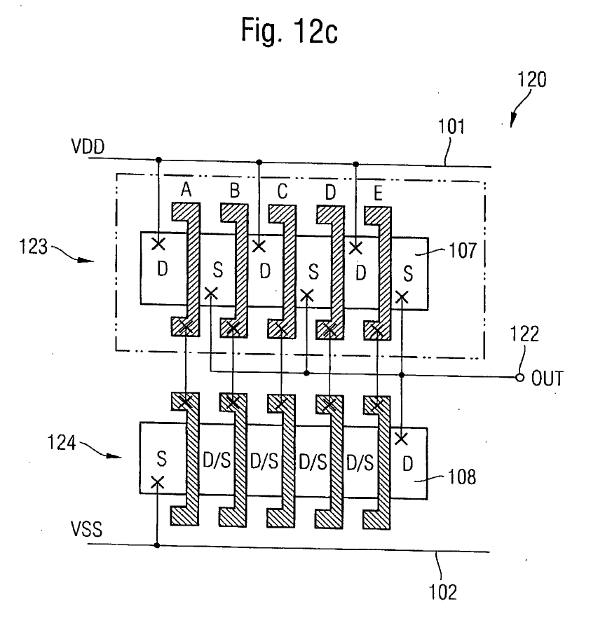

FIGS. 12A-12C show the implementation of a five input NAND element by providing one single basic cell 100 such as that shown in FIG. 10.

The NAND element 120 comprises five input terminals 121 for receiving five input variables A0-E0 and a single output terminal 122 for providing an output signal OUT (see FIG. 12A). FIG. 12B shows the equivalent circuit of this NAND element 120. The NAND element 120 comprises five PMOS transistors 123 and five NMOS transistors 124. The PMOS transistors 123 are arranged with respect to their conductive path in parallel to each other and between the first supply terminal 101 and the output terminal 122. The NMOS transistors 124 are arranged with regard to their conductive path in series connection to each other and between the output terminal 122 and the second supply terminal 102. The input variables A0-E0 form the control signals of these PMOS transistors 123 and NMOS transistors 124. FIG. 12C shows the layout, which is also denoted as stick diagram, for an implementation of the NAND element 120 using a single basic cell 100 shown in FIG. 10. The gate terminals of each adjacent PMOS and NMOS transistors 123, 124 are shortened in order that each of them receives the same input variables A0-E0.

The regions within the doped region 107, 108 which are arranged between adjacent transistor gates form a shared drain region, a shared source region or a region which forms for one of the transistors 107, 108 the drain region and for the adjacent transistor 107, 108 the source region. In FIG. 12C a shared drain region is referenced by D, a shared source region is referenced by S and a region which at the same time forms a source region and a drain region for two adjacent transistors is referenced by D/S.

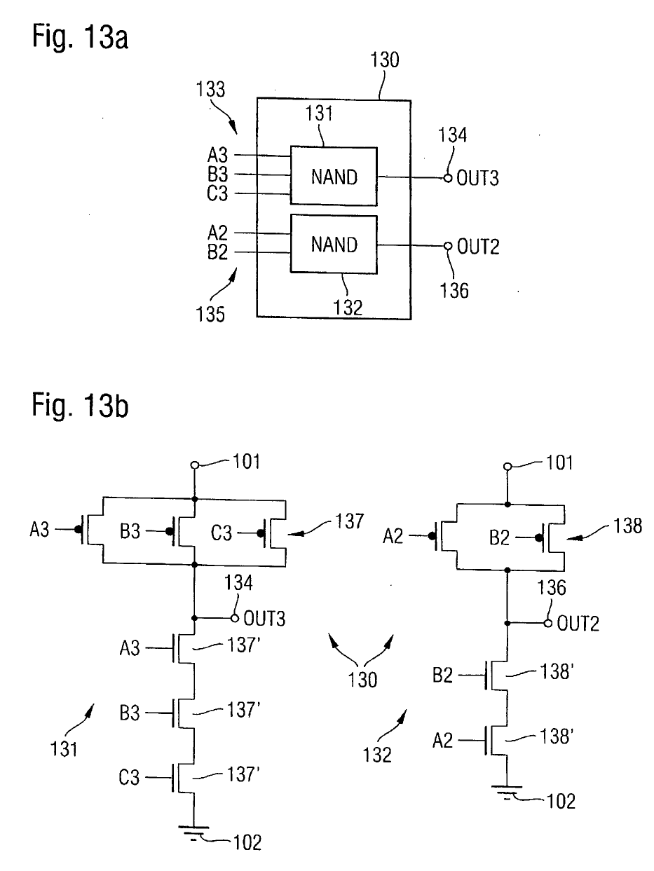

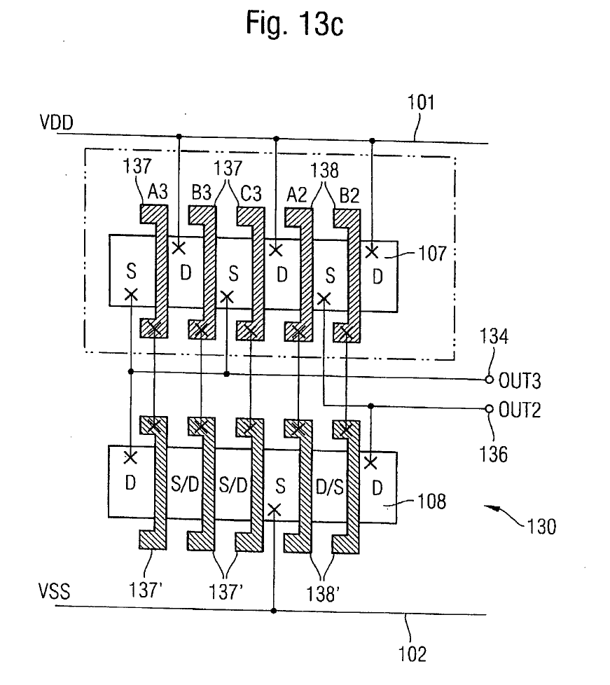

FIGS. 13A-13C show the implementation of one two-input NAND element and one three-input NAND element using one single basic cell of FIG. 10.

FIG. 13A shows a further logic element 130. The logic element 130 comprises a first NAND element 131 and a second NAND element 132. The first NAND element 131 comprises three input terminals 133 for receiving three input variables A3-C3 and a single output terminal 134 for a first output signal OUT3. The second NAND element 132 comprises two input terminals 135 for receiving two input variables A2, B2 and a single output terminal 136 for a second output signal OUT2. FIG. 13B shows the equivalent circuit of the NAND elements 131, 132 shown in FIG. 13A. As is shown in FIG. 13B the first NAND element 131 comprises three PMOS transistors 137 and three NMOS transistors 137′ and the second NAND element 132 comprises two PMOS transistors 138 and two NMOS transistors 138′. The circuitry of these PMOS and NMOS transistors is similar to that shown in FIG. 12B. Here, having the two single NAND elements 131, 132, the interconnection of the different PMOS and NMOS transistors is also similar to those shown in FIG. 12C with the difference that in the layout arrangement according to FIG. 13C, two output terminals 134, 136 for tapping off two output signals OUT2, OUT3 are provided.

In this embodiment, both NAND elements 131, 132 and their respective PMOS and NMOS transistors 137, 137′, 138, 138′ are incorporated within the same basic cell 100 and thus use the same doped regions 107, 108 within the respective transistor regions 103, 104 of the basic cell 100. Only the interconnection of the different transistors 137, 137′, 138, 138′ with respect to the output terminals 134, 136, the supply terminals 101, 102 and also with respect to the interconnection of the transistors 137, 137′, 138, 138′ to each other is different compared to the five input NAND elements 120 shown in FIG. 12.

FIGS. 14A-14C show the implementation of one five input NOR element using one and a half basic cells such as those shown in FIG. 10.

FIG. 14A shows a NOR element 140 having five input terminals 141 for receiving five input variables A0-E0 and one output terminal 142 for providing an output signal OUT. FIG. 14B shows the equivalent circuit of this NOR element 140. The NOR element 140 comprises five NMOS transistors and five so-called double width PMOS transistors. Each one of these double width PMOS transistors comprises a double channel width compared to a “normal” single width channel PMOS transistor. In order to at least partly compensate the reduced mobility of a normal single width channel PMOS transistor compared to a normal single width channel NMOS transistor with a given channel width each logic double width PMOS transistor is implemented as the parallel circuit of two single width channel PMOS transistors. In order to at least partially compensate the reduced conductance of a series stack of PMOS transistors, each one of the PMOS transistors 143 is build out of two PMOS transistors (or PMOS devices) of single width in parallel, thus electrically forming a device of double channel width of each of them. Further, PMOS devices may be added in parallel in an analogous manner to even improve the described behaviour. Thus, the NOR element 140 comprises altogether ten single width channel PMOS transistors 143 and five single width channel NMOS transistors 144.

All NMOS transistors 144 are arranged in parallel to each other between the output terminal 142 and the second supply terminal 102. A first plurality of five of the PMOS transistors 143 are connected in series between the first supply terminal 101 and the output terminal 142 and a second plurality of five of the PMOS transistors 143 (which form the double channel width) are connected in series between the first supply terminal 101 and the output terminal 142.

For the implementation of the NOR element 140, altogether one and a half basic cells 100 as shown in FIG. 10 are provided. FIG. 14C shows the layout of such a NOR element 140 using 1,5 basic elements 100 which are arranged adjacent to each other. The interconnection of the gate, source and drain regions of the respective transistors 143, 144 with regard to the supply lines 101, 102 and input and output terminals 141, 142 may be provided as already described above.

In the layout arrangement shown in FIG. 14C, by providing two of the basic cells 100, five additional NMOS transistors 145 in the upper part of the layout are not used for providing the logic element and therefore are not yet interconnected at all. However, the NMOS transistors 145 may be used for other purposes or applications.

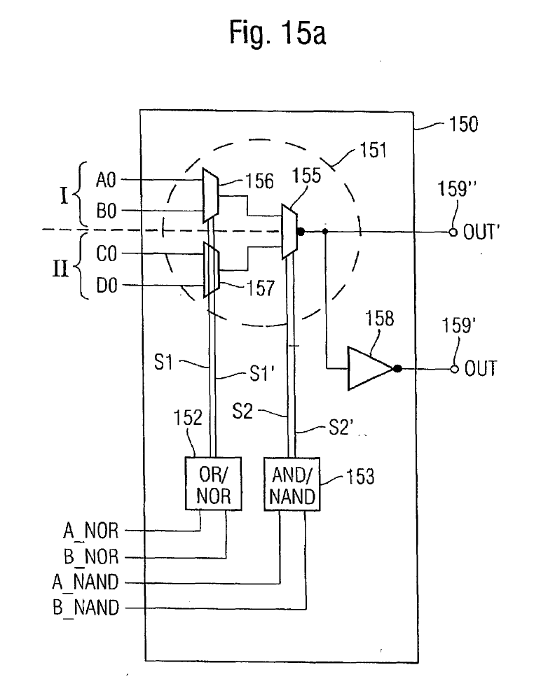

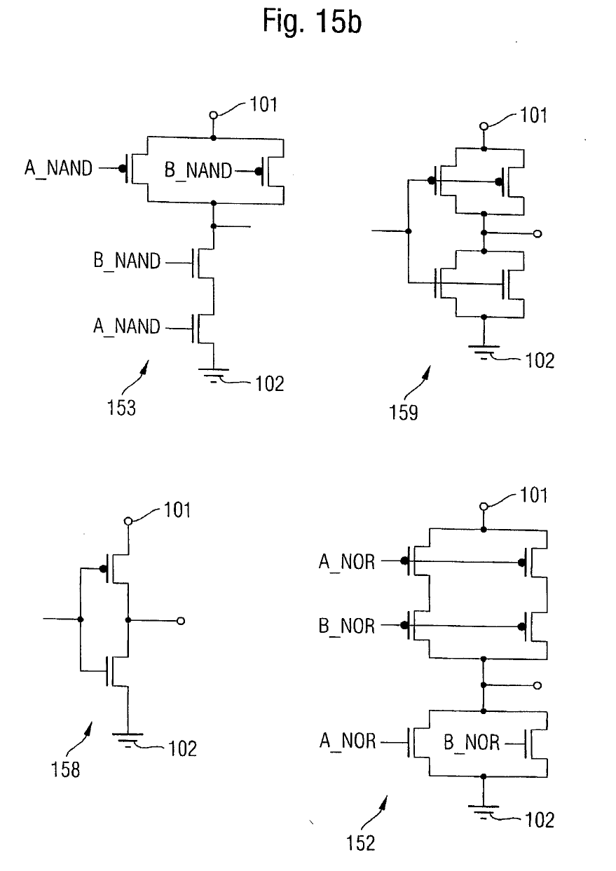

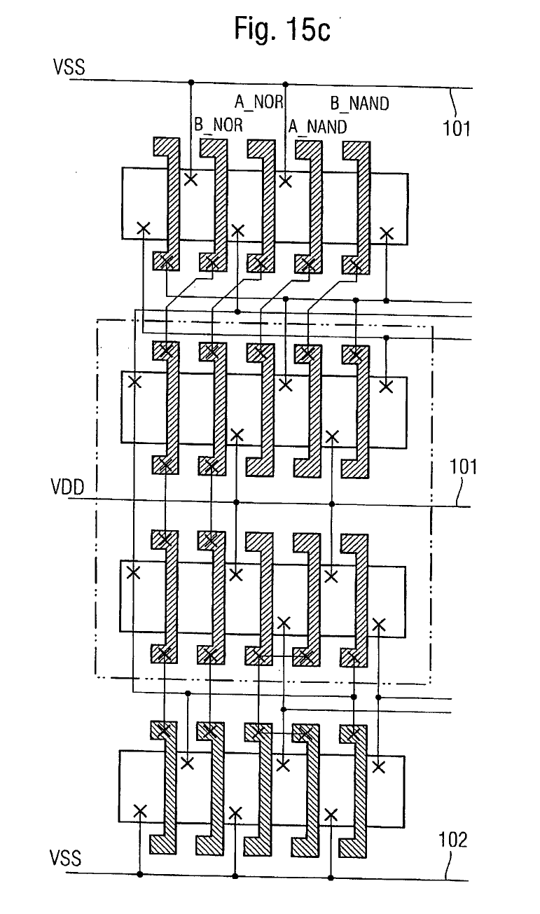

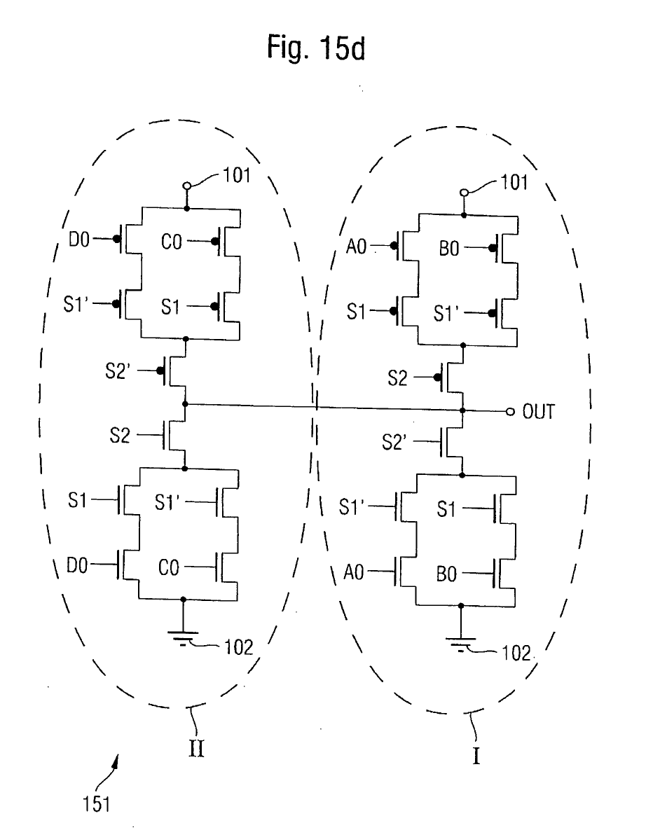

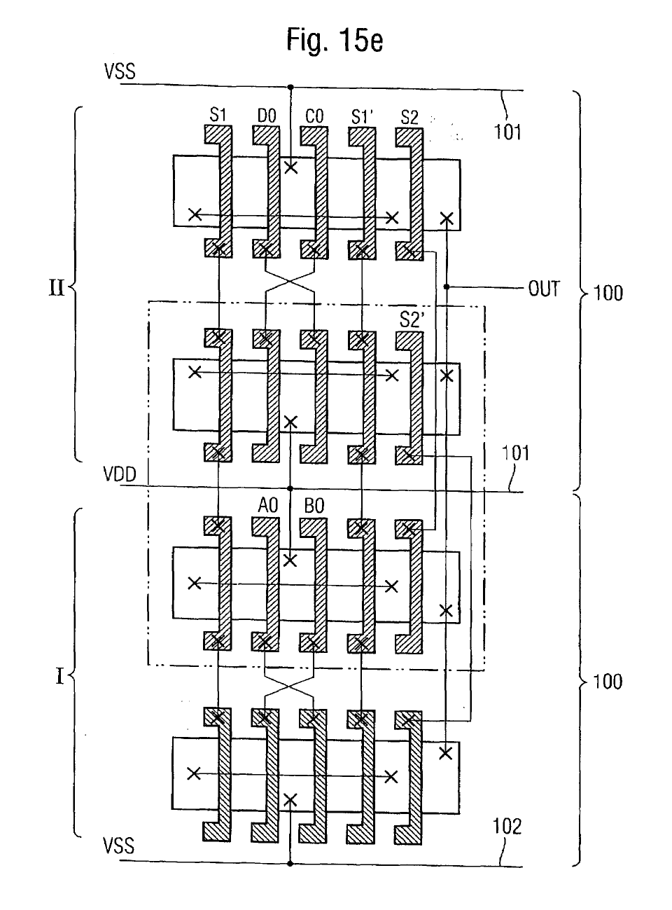

FIGS. 15A-15F show the implementation of a MUX-based configurable cell using four basic cells of FIG. 10.

FIG. 15 shows a block diagram of a multiplexer based configurable cell 150 or short MUX-based cell 150 similar to the one illustrated in FIG. 3. This MUX-based cell 150 is denoted with reference symbol 150. The MUX-based cell 150 comprises one 4:1 multiplexer 151 such as that shown in FIG. 1B, which comprises three 2:1 multiplexers 155-157. The multiplexers 156, 157 receive four input variables A0-D0 and the multiplexer 155 provides an output variable. All of the 2:1 multiplexers 155-157 within the 4:1 multiplexer 151 receive a selection signal S1, S2 as well as their complementary selection signals S1′, S2′. The inverters which are necessary for realizing the signal inversion of S1, S2 are not shown in FIG. 15A, but are considered to be implemented in the bottom part (i.e. as parts of the AND-NAND and OR-NOR elements 152, 153) of the MUX-based cell 150.

The MUX-based cell 150 further comprises one OR-NOR element 152 and one AND-NAND element 153 each having two input terminals and two output terminals. The OR-NOR element 152 is designed to receive two input variables A_NOR, B_NOR and to provide the two output variables S1, S1′ as selection signals for the two 2:1 multiplexers 156, 157 in the lowest hierarchical level of the 4:1 multiplexer 150. The AND-NAND element 153 is designed to receive two input variables A_NAND, B_NAND and to provide the two output variables S2, S2′ as selection signals for the highest level 2:1 multiplexer 155.

The multiplexer 155 is considered to provide an inverted output signal OUT′. The MUX-based cell 150 is designed to generate at a first output terminal 159′ a first output signal OUT and at a second output terminal 159″ a second output signal OUT′ which is inverted to the first output signal OUT.

Instead of using a single OR-NOR-element 152 and a single AND-NAND-element 153 it may also be possible to implement the MUX-based cell 150 by using a separate OR-element and a separate NOR-element for the OR-NOR-element 152 and a separate AND-element and a separate NAND-element instead of the AND-NAND-element 153.

For the implementation of the 4:1 multiplexer 151 two basic cells 100 are necessary. For the implementation of the OR-NOR element 152, the AND-NAND element 153 and all necessary inverters 158 again two basic cells 100 are required.

FIG. 15B shows the equivalent circuits for a two input AND-NAND element 153, a two input OR-NOR element 152 (with compensated channel width of the PMOS transistors), a single inverter 158 and a double width inverter 159. For the implementation of these elements two basic cells 100 are provided. FIG. 15C shows the corresponding layout showing the straight forward interconnection by using two different basic cells 100 according to at least some embodiments of the present invention.

The 4:1 multiplexer shown in FIG. 15A is divided in an upper part I and a lower part II. The upper part I comprises the 2:1 multiplexer 156 and the upper half of the 2:1 multiplexer 155. The lower part II comprises the 2 ;1 multiplexer 157 and the lower half of the 2:1 multiplexer 155. The equivalent circuit of this 4:1 multiplexer 151 is shown in FIG. 15D. The right part of the circuit shown in FIG. 15D represents the upper part I of the 4:1 multiplexer 151 and the left part of this circuit represents the lower part II of the 4:1 multiplexer 151. The corresponding layout is shown in FIG. 15F. As stated before, the 4:1 multiplexer 151, that is for the three 2:1 multiplexers 155-157 within this 4:1 multiplexer 151 requires two basic cells 100.

Thus, a total amount of four basic cells 100 are needed for the MUX-based configurable cell as shown in FIG. 15A.

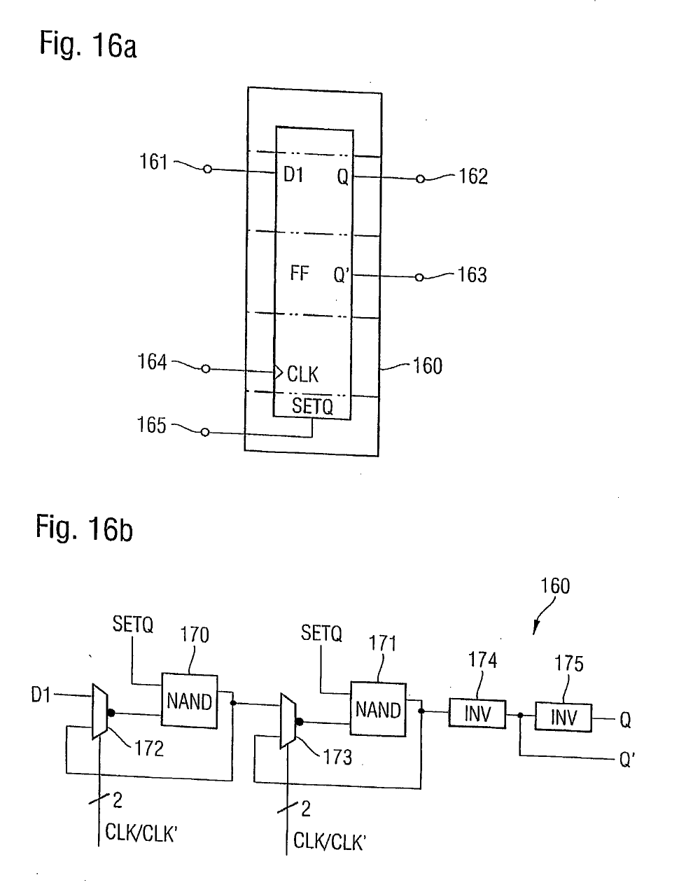

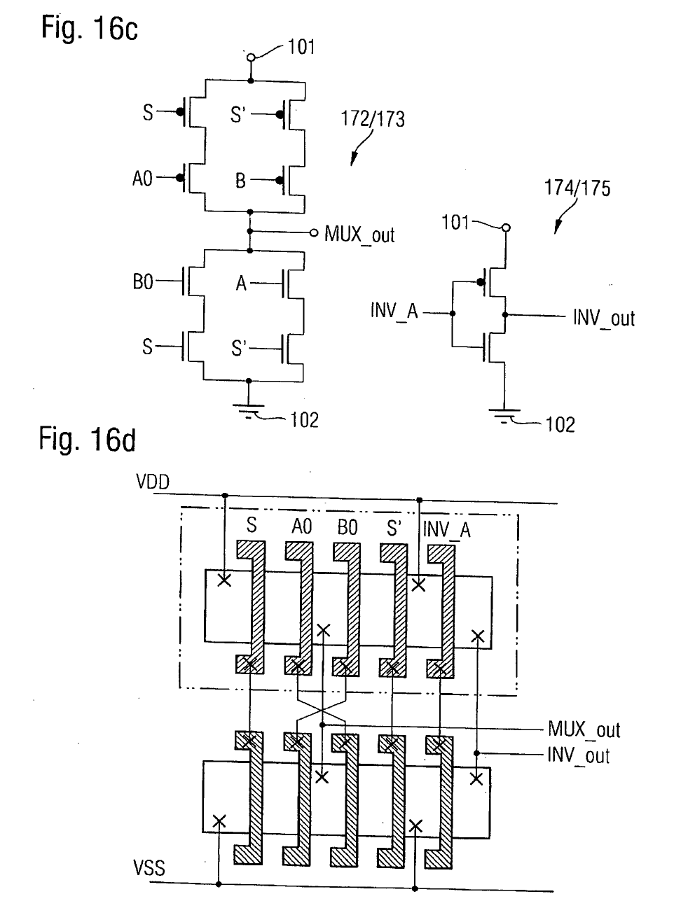

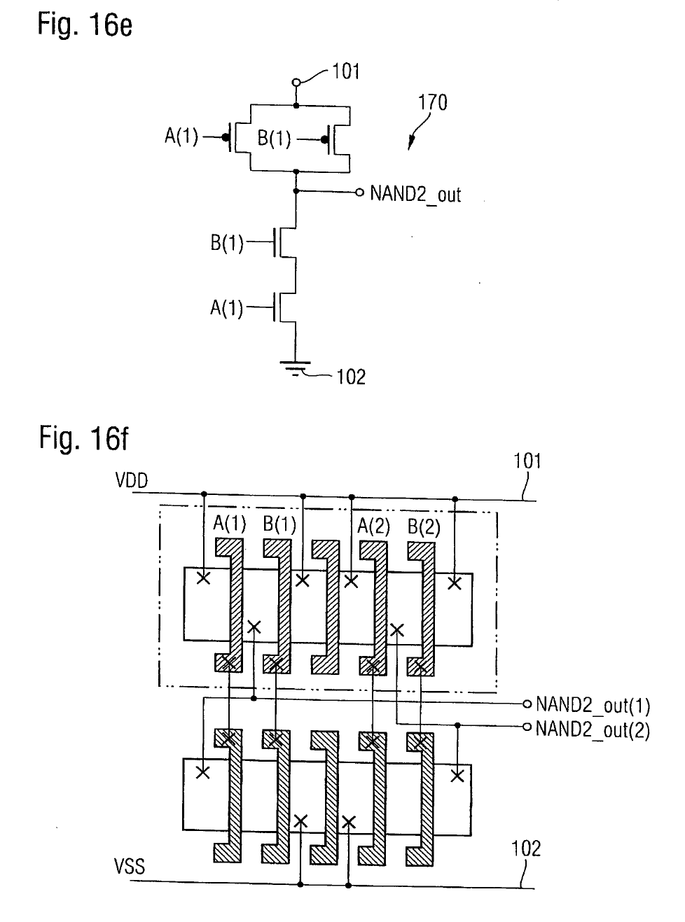

FIGS. 16A-16F show the implementation of a settable D flip-flops using three basic cells of FIG. 10.

FIG. 16A shows a block diagram of a settable D flip-flop. The settable D flip-flop 160 comprises a data input terminal 161 for receiving a data signal D1 and two data output terminals 162, 163 for providing two data output signals Q, Q′, whereas the data signal Q′ is inverted with regard to the data signal Q. The settable D flip-flop 160 further comprises a clock terminal 164 for receiving a clock signal CLK and a set terminal 165 for receiving a set signal SETQ, which is for example active low.

FIG. 16B shows a block diagram for the realization of the settable D flip-flop 160. The D flip-flop 160 comprises two NAND elements 170, 171, two multiplexers 172, 173 and two inverters 174, 175. The selection signal of the multiplexers 172, 173 is provided by a complementary pair of clock signals CLK, CLK′ globally generated outside the settable D-flip-flop 160in FIG. 16A. The data signal D1 is provided to a first input of the first multiplexer 172 which generates an output signal which is together with the set signal SETQ provided to the first NAND element 170. The output signal of the first NAND element 170 is provided as a data signal to the downstream arranged second multiplexer 173 and in addition to that via a feedback line to a second input terminal of the first 2:1 multiplexer 172. The second multiplexer 173 and the second NAND element 171 are arranged in similar configuration as the first NAND element 170 and the first multiplexer 172. The output data signal of the second NAND element 171 is fed into a first inverter 174 which generates the inverted output data signal Q′. Additionally, a second optional inverter 175 is provided which generates the optional output signal Q out of the inverted output signal Q′.

FIG. 16C shows the equivalent circuit of one single 2:1 multiplexer 172, 173 and one single inverter 174, 175. FIG. 16D shows the corresponding layout for the implementation of a single multiplexer 172, 173 and a single inverter 174, 175, such as shown in FIG. 16C, by using one single basic cell 100 according to some embodiments of the present invention. It should be noted that for the provision of the two multiplexers 172, 173 and the two inverters according to the block diagram in FIG. 16B, two basic cells 100 as shown in FIG. 16D are provided.

In FIGS. 16C and 16D MUX_out refer to the output signal of the corresponding multiplexers 172, 173 and INV_out refers to the output signals of the corresponding inverters 174, 175.

FIG. 16E shows the equivalent circuit of a single NAND element 170, 171. For the implementation of a settable D flip-flop 160 according to FIG. 16A two of these NAND elements 170, 171 are necessary. FIG. 16F shows the corresponding layout for the implementation of these two NAND elements 170, 171 by using a single basic element 100 according to at least one embodiment of the present invention.

In FIGS. 16E and 16F NAND2_out(1) and NAND2_out(2) refer to the output signals of the corresponding NAND elements 171, 172.

Thus, a total number of three basic cells 100 are needed for the D-flip flop 160 in FIG. 16A. It is noted, that as well the innermost PMOS transistors and the NMOS transistors remain unused in this application in FIGS. 16D and 16F.

Additional functionalities such as ENABLE and/or SCAN can also be implemented by introducing previously mentioned concepts and structures such as 4:1 multiplexers for the master stage, etc.

It is also noted that the above mentioned embodiments and examples should be understood to be only exemplary. Thus, additional logic elements, circuit arrangements and functional circuits may be implemented using one or more of the basic elements such as shown in FIG. 10 or by using other examples of basic elements by varying the number of PMOS and/or NMOS transistors within the respective strip.

Referring back to FIG. 8, FIG. 8 shows (in dotted lines) a further embodiment of the present invention for example in case the semiconductor manufacturer generates a very special library which is just adapted on the corresponding placement of the customer. Such a library may be constructed on the basis of a basic cell as shown in FIG. 10 or the respective MUX-based cell array as shown in FIG. 9. In this case it will be possible to bypass the step 86 of mask programmable routing by creating and providing a customer/manufacturer specific library 89 which allows after the multiplexer synthesis 82 and the respective placement step 83 to proceed directly to the step of the mask generation 87.

While embodiments and applications of this invention have been shown and described above it would be apparent to those skilled in the art that many more modifications than mentioned above are possible without departing from the inventive concepts described herein. The invention, therefore, is not restricted except in the spirit of the appended claims.

It is therefore intended that the foregoing detailed description is to be regarded as illustrative rather than limiting and that it is understood that it is the following claims including all equivalents described in the claims that are intended to define the spirit and the scope of this invention. Nor is anything in the foregoing description intended to disavow the scope of the invention as claimed or any equivalents thereof.

Embodiments of the present invention are suitable for example for use with programmable logic circuits such as FPGAs. However, it is not restricted to this embodiment and can also be used, for example, with PLDs (programmable logic devices) or PLAs (programmable logic arrays), at least partially cell-based circuit designs, etc.

What we claim is:

1. A mask programmable logic cell for configuration of at least one either LUT-based or MUX-based configurable cell, comprising:
a first set of 2:1 multiplexers each comprising at least two input terminals and at least one select terminal,
a second set of 4:1 multiplexers each comprising at least four input terminals and at least two select terminals.

2. The mask programmable logic as claimed in claim 1, wherein each of the 4:1 multiplexers of the second set comprises three hierarchically arranged 2:1 multiplexers.

3. The mask programmable logic cell as claimed in claim 1, wherein an amount N of input terminals of the configurable cells is at least 4.

4. The mask programmable logic cell as claimed in claim 3, wherein the first set comprises six 2:1 multiplexers.

5. The mask programmable logic cell as claimed in claim 3, wherein the second set comprises three 4:1 multiplexers.

6. The mask programmable logic cell as claimed in claim 1, further comprising at least one buffer.

7. The mask programmable logic cell as claimed in claim 1, further comprising at least one inverter.

8. The mask programmable logic cell as claimed in claim 1, further comprising one flip-flop.

9. A LUT-based configurable cell, comprising at least one LUT and configured by at least one mask programmable logic cell, each of the mask programmable logic cells comprising a first set of 2:1 multiplexers each comprising two input terminals and at least one select terminal and a second set of 4:1 multiplexers each comprising four input terminals and at least two select terminals.

10. The LUT-based configurable cell according to claim 9, wherein each of the 4:1 multiplexers of the second set comprises three hierarchically arranged 2:1 multiplexers.

11. The LUT-based configurable cell as claimed in claim 9, wherein an amount N of input terminals of the configurable cells is at least 4.

12. The LUT-based configurable cell as claimed in claim 11, wherein the first set comprises six 2:1 multiplexers and the second set comprises three 4:1 multiplexers.

13. The LUT-based configurable cell as claimed in claim 11, wherein the LUT is configured by using one single mask programmable logic cell comprising six 2:1 multiplexers and three 4:1 multiplexers, wherein the 2:1 multiplexers and 4:1 multiplexers are arranged within a hierarchical multiplexer tree comprising four hierarchical levels.

14. The LUT-based configurable cell as claimed in claim 13, further comprising a set of memory cells, wherein each of the memory cells is designed to store one input variable and to be connected with one input terminal of one of the 2:1 multiplexer within the lowest hierarchical level of the multiplexer tree.

15. The LUT-based configurable cell as claimed in claim 9, further comprising a flip-flop arranged between an output of the LUT and a first output terminal of the LUT-based configurable cell.

16. The LUT-based configurable cell as claimed in claim 15, wherein the output of the LUT is further connected to a second output terminal of the LUT-based configurable cell.

17. A MUX-based configurable cell arrangement, comprising at least one combinational MUX-based configurable cell implemented from resources of a mask programmable logic cell wherein the resources comprise a first set of 2:1 multiplexers each comprising two input terminals and at least one select terminal and a second set of 4:1 multiplexers each comprising four input terminals and at least two select terminals.

18. The MUX-based configurable cell according to claim 17, wherein each of the 4:1 multiplexers of the second set comprises three hierarchically arranged 2:1 multiplexers.

19. The MUX-based configurable cell as claimed in claim 17, wherein the combinational MUX-based configurable cell comprises one 4:1 multiplexer, one logic OR-element and one logic AND-element.

20. A MUX-based configurable cell arrangement, comprising at least one sequential MUX-based configurable cell implemented from resources of a mask programmable logic cell wherein the resources comprise, a first set of 2:1 multiplexers each comprising two input terminals and at least one select terminal and a second set of 4:1 multiplexers each comprising four input terminals and at least two select terminals.

21. The MUX-based configurable cell according to claim 20, wherein each of the 4:1 multiplexers of the second set comprises three hierarchically arranged 2:1 multiplexers.

22. The MUX-based configurable cell as claimed in claim 20, wherein the sequential MUX-based configurable cell comprises one 4:1 multiplexer, one logic OR-element, one logic AND-element and one flip-flop.

23. The MUX-based configurable cell as claimed in claim 20, wherein the MUX-based configurable cell arrangement further comprises two combinational MUX-based configurable cell implemented from resources of the mask programmable logic cell and one sequential MUX-based configurable cell.

24. A configurable logic array comprising a plurality of configurable cells and further comprising:
at least one LUT-based configurable cell, comprising at least one LUT implemented from resources of a mask programmable logic cell wherein the resources comprise a first set of 2:1 multiplexers each comprising two input terminals and at least one select terminal and a second set of 4:1 multiplexers each comprising four input terminals and at least two select terminals,
and
at least one MUX-based configurable cell arrangement, comprising at least one MUX-based configurable cell implemented from resources of the mask programmable logic cell.

25. The MUX-based configurable cell according to claim 24, wherein each of the 4:1 multiplexers of the second set comprises three hierarchically arranged 2:1 multiplexers.

26. A mask programmable basic cell for a mask programmable gate array (MPGA), the mask programmable basic cell comprising:
a first and a second supply line,
a first transistor strip to provide a first amount of first transistors of a first conductivity type,
a second transistor strip to provide a second amount of second transistors of a second conductivity type opposite to the first conductivity type.

27. The mask programmable basic cell as claimed in claim 26, wherein the first and the second amount are equal.

28. The mask programmable basic cell as claimed in claim 27, wherein the first and second amount is five or ten.

29. The mask programmable basic cell as claimed in claim 27, wherein the first and second amount is four or six.

30. The mask programmable basic cell as claimed in claim 26, wherein the first amount is twice the second amount.

31. The mask programmable basic cell as claimed in claim 26, wherein the first transistors are arranged adjacent to the first supply line and the second transistors are arranged adjacent to the second supply line.

32. The mask programmable basic cell as claimed in claim 26, wherein the first and second transistors are field effect controlled transistors.

33. The mask programmable basic cell as claimed in claim 32, wherein the first transistors are PMOS transistors and the second transistors are NMOS transistors.

34. The mask programmable basic cell as claimed in claim 26, wherein adjacent transistors of the first transistors and second transistors comprise a doped region.

35. The mask programmable basic cell as claimed in claim 30, wherein all adjacent transistors of the first transistors and all adjacent transistors of the second transistors comprise respectively a doped region.

36. The mask programmable basic cell as claimed in claim 30, wherein all of the first transistors are arranged in a first row on the first transistor strip and all of second transistors are arranged in a second row on the second transistor strip.

37. The mask programmable basic cell as claimed in claim 36, wherein at least one of the first and second row is linear.

38. A mask programmable gate array, comprising:
a plurality of input/output terminals,
an array comprising a plurality of mask programmable basic cells, the layout of the mask programmable basic cell comprising a first and a second supply line, a first transistor strip to provide a first amount of first transistors of a first conductivity type, and a second transistor strip to provide a second amount of second transistors of a second conductivity type opposite to the first conductivity type.

39. The mask programmable gate array as claimed in claim 38, wherein the first and the second amount is five or ten.

40. The mask programmable gate array as claimed in claim 38, wherein the first amount is twice the second amount.

41. The mask programmable gate array as claimed in claim 38, wherein the first transistors are arranged adjacent to the first supply line and the second transistors are arranged adjacent to the second supply line.

42. The mask programmable gate array as claimed in claim 38, wherein the first transistors are PMOS transistors and the second transistors are NMOS transistors.

43. The mask programmable gate array as claimed in claim 38, further comprising at least one first NAND-element having five input terminals and one output terminal, wherein each one of the NAND-elements is realized my means of one single mask programmable basic cell.

44. The mask programmable gate array as claimed in claim 38, further comprising at least one logic element, each of the logic elements comprising one second NAND-element having two input terminals and one output terminal and one third NAND-element having three input terminals and one output terminal, wherein each one of the logic elements is realized my means of one single mask programmable basic cell.

45. The mask programmable gate array as claimed in claim 38, further comprising at least one first NOR-element having five input terminals and one output terminal, wherein each one of the NOR-elements is realized by means of two single mask programmable basic cells which are arranged adjacent to each other to provide PMOS transistors with double width.

46. The mask programmable gate array as claimed in claim 38, further comprising at least one MUX-based configurable cell comprising a 4:1 multiplexer, a OR-NOR-element and a AND-NAND-element each having two input terminals, wherein the OR-NOR-element has a first and second output to provide complementary signals and wherein the AND-NAND-element has a third and fourth output to provide complementary signals.

47. The mask programmable gate array as claimed in claim 46, wherein each one of the MUX-based configurable cells is realized by means of four single mask programmable basic cells which are arranged adjacent to each other

48. The mask programmable gate array as claimed in claim 46, wherein each of the MUX-based configurable cells comprises one hierarchical arranged 4:1 multiplexer comprising three 2:1 multiplexers.

49. The mask programmable gate array as claimed in claim 46, further comprising at least one inverter.

50. The mask programmable gate array as claimed in claim 38, further comprising at least one D-flip flop, wherein each one of the D-flip flops is realized my means of at least two single mask programmable basic cells which are arranged adjacent to each other.

51. The mask programmable gate array as claimed in claim 50, wherein the D-flip-flop is a settable D-flip-flop comprises two fourth NAND-elements, two 2:1 multiplexers and at least one inverter arranged in series connection to each other with the inverter arranged at the output side of the D-flip-flop and one 2:1 multiplexer and one NAND-element each form a stage of the D-flip-flop.

52. The mask programmable gate array as claimed in claim 38, further comprising at least one common first supply line and at least one common second supply line commonly, each one of the common first and second supply lines is designed to be used by at least two mask programmable basic cells.

53. The mask programmable gate array as claimed in claim 38, further comprising at least one data line to provide a static signal related to a first logical level.

54. A method for generating a mask for a mask programmable gate array using mask programmable logic cells for configuration of at least one either LUT-based or MUX-based configurable cell comprising:
providing an user defined design of an integrated circuit;
performing a logic synthesis depending on the defined design of the integrated circuit.

55. The method as claimed in claim 54, wherein the mask programmable logic cell comprising:
a first set of 2:1 multiplexers each comprising at least two input terminals and at least one select terminal,
a second set of 4:1 multiplexers each comprising at least four input terminals and at least two select terminals.

56. The method as claimed in claim 54, further comprising after the step of performing a logic synthesis:
performing a mask programmable routing for the integrated circuit;
performing a mask generation for the integrated circuit;
chip fabrication of the integrated circuit.

57. The method as claimed in claim 54, wherein the logic synthesis comprises the step of a multiplexer based synthesis followed by a corresponding first placement step.

58. The method as claimed in claim 54, wherein the logic synthesis comprises the step of a LUT-based synthesis followed by a corresponding second placement step.

59. The method as claimed in claim 54, wherein the method allows for the same integrated circuit a LUT-based synthesis and multiplexer based synthesis during the step of performing a logic synthesis.

60. The method as claimed in claim 54, wherein the design is a FPGA-circuit.

61. The method as claimed in claim 54, wherein the design is a MPGA-circuit.

62. The method as claimed in claim 54, further comprising the generation of a manufacturer specific library which is adapted on the corresponding logic synthesis and which is constructed on the basis of a mask programmable basic cell.

63. The method as claimed in claim 62, wherein the mask programmable basic cell comprising:
a first and a second supply line,
a first transistor strip to provide a first amount of first transistors of a first conductivity type,
a second transistor strip to provide a second amount of second transistors of a second conductivity type opposite to the first conductivity type.

64. The method as claimed in claim 62, wherein after the step of logic synthesis the method proceeds without a step of performing a mask programmable routing directly with the steps of:
performing a mask generation for the integrated circuit;
chip fabrication of the integrated circuit.
